(19) United States
(12) Patent Application Publication
(10) Pub. No.: US 2026/0068311 A1
(43) Pub. Date: Mar. 5, 2026

(54) SEMICONDUCTOR DEVICE

(71) Applicant: Samsung Electronics Co., Ltd., Suwon-si (KR)

(72) Inventors: Jaeho Jeon, Suwon-si (KR); Minwoo Kim, Suwon-si (KR); Seongkwang Kim, Suwon-si (KR); Donghoon Hwang, Suwon-si (KR); Hyunsoo Kim, Suwon-si (KR); Byungho Moon, Suwon-si (KR); Wonchang Lee, Suwon-si (KR)

(21) Appl. No.: 19/310,778

(22) Filed: Aug. 26, 2025

(30) Foreign Application Priority Data
Aug. 29, 2024 (KR) 10-2024-0116851

(51) Int. Cl. H10D 84/85; H10D 84/01

(52) U.S. Cl. CPC H10D 84/856; H10D 84/0167; H10D 84/017; H10D 84/0184; H10D 84/0188; H10D 84/851

(57) ABSTRACT

An example semiconductor device may include a first semiconductor pattern and a second semiconductor pattern overlapping each other, a gate electrode including an electrode portion between the first semiconductor pattern and the second semiconductor pattern, an inner spacer contacting a top surface of the first semiconductor pattern and a bottom surface of the second semiconductor pattern, a two-dimensional layer contacting the first semiconductor pattern, the second semiconductor pattern, and the inner spacer, and a source/drain pattern on the two-dimensional layer.

### CROSS-REFERENCE TO RELATED APPLICATION

This application claims priority under 35 U.S.C. § 119 to Korean Patent Application No. 10-2024-0116851, filed on Aug. 29, 2024, in the Korean Intellectual Property Office, the entire contents of which are hereby incorporated by reference.

### BACKGROUND

A semiconductor device includes an integrated circuit consisting of metal-oxide-semiconductor field-effect transistors (MOS-FETs). To meet an increasing demand for the semiconductor device with a small pattern size and a reduced design rule, the MOS-FETs are scaled down. The scale-down of the MOS-FETs may lead to deterioration in operation characteristics of the semiconductor device. Accordingly, a variety of studies are conducted to overcome technical limitations associated with the scale-down of the semiconductor device and to provide high performance semiconductor device.

### SUMMARY

The present disclosure relates to a semiconductor device with improved electrical and reliability characteristics.

In general, according to some aspects, a semiconductor device may include a first semiconductor pattern and a second semiconductor pattern, which are overlapped with each other, a gate electrode including an electrode portion between the first and second semiconductor patterns, an inner spacer in contact with a top surface of the first semiconductor pattern and a bottom surface of the second semiconductor pattern, a two-dimensional layer in contact with the first semiconductor pattern, the second semiconductor pattern, and the inner spacer, and a source/drain pattern on the two-dimensional layer.

In general, according to some aspects, a semiconductor device may include a first semiconductor pattern and a second semiconductor pattern, which are overlapped with each other, a gate electrode including an electrode portion between the first and second semiconductor patterns, a two-dimensional layer in contact with the first semiconductor pattern and the second semiconductor pattern, an inner spacer between the two-dimensional layer and the electrode portion, and a source/drain pattern on the two-dimensional layer. The inner spacer may include a first side surface, which is in contact with the two-dimensional layer, and a second side surface, which is opposite to the first side surface. An area of the first side surface of the inner spacer may be smaller than an area of the second side surface of the inner spacer.

In general, according to some aspects, a semiconductor device may include a first semiconductor pattern and a second semiconductor pattern, which are overlapped with each other, a gate electrode including an electrode portion between the first and second semiconductor patterns, an inner spacer in contact with a top surface of the first semiconductor pattern and a bottom surface of the second semiconductor pattern, a gate insulating layer between the inner spacer and the electrode portion, a two-dimensional layer in contact with a side surface of the first semiconductor pattern, a side surface of the second semiconductor pattern, and a first side surface of the inner spacer, a source/drain pattern on the two-dimensional layer, and an active contact electrically connected to the source/drain pattern. The side surface of the first semiconductor pattern, the side surface of the second semiconductor pattern, and the first side surface of the inner spacer may be coplanar with each other.

### BRIEF DESCRIPTION OF THE DRAWINGS

FIG. 1A is a plan view illustrating an example of a semiconductor device.

FIG. 1B is an example sectional view taken along a line A-A′ of FIG. 1A.

FIG. 1C is an example sectional view taken along a line B-B′ of FIG. 1A.

FIG. 1D is an example sectional view taken along a line C-C′ of FIG. 1A.

FIG. 1E is an example sectional view taken along a line D-D′ of FIG. 1A.

FIG. 1F is an example enlarged view illustrating a portion ‘Q1’ of FIG. 1B.

FIGS. 2A, 2B, 2C, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16, 17, 18A, 18B, 19A, 19B, 20A, 20B, 21A, and 21B are diagrams illustrating an example of a method of fabricating the semiconductor device of FIGS. 1A to 1F.

FIG. 22 is a sectional view illustrating an example of a semiconductor device.

### DETAILED DESCRIPTION

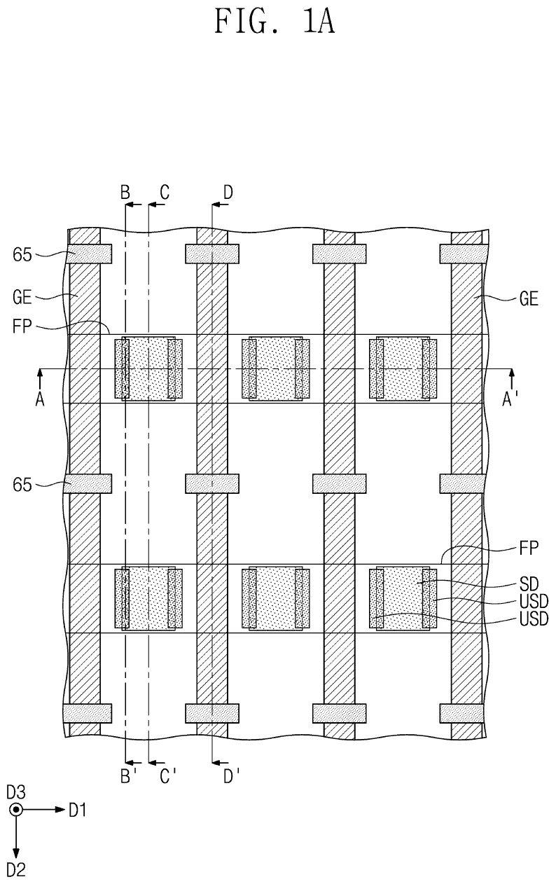

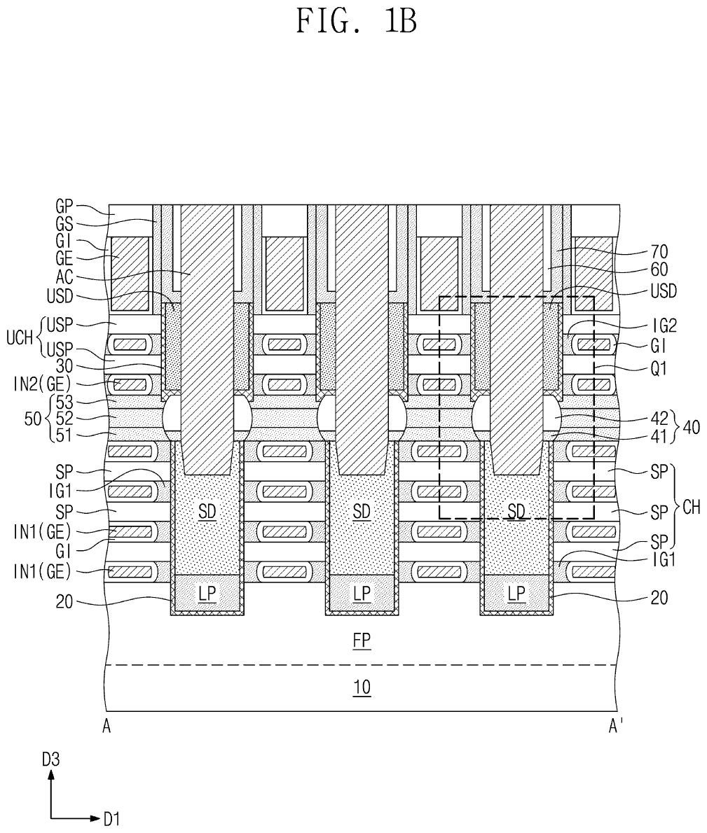

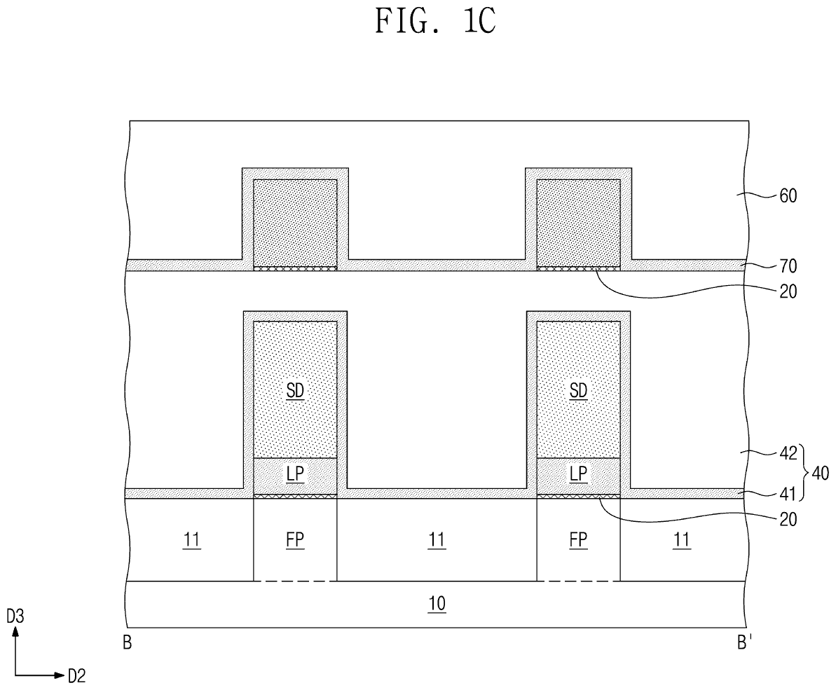

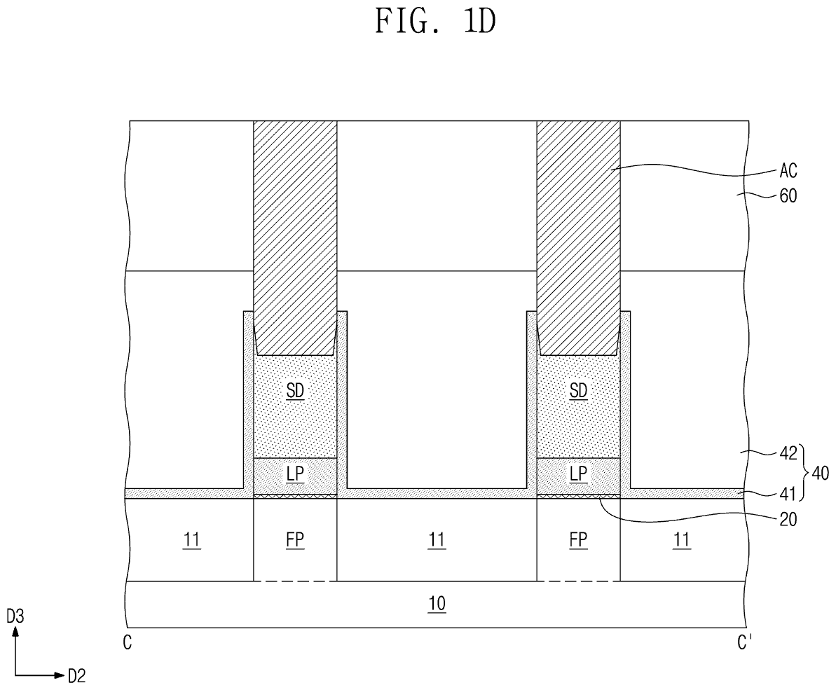

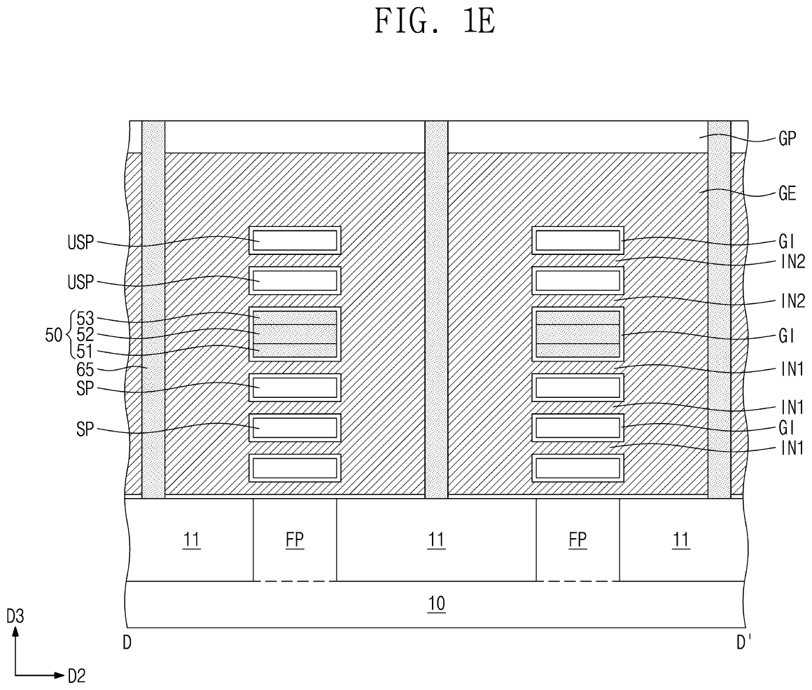

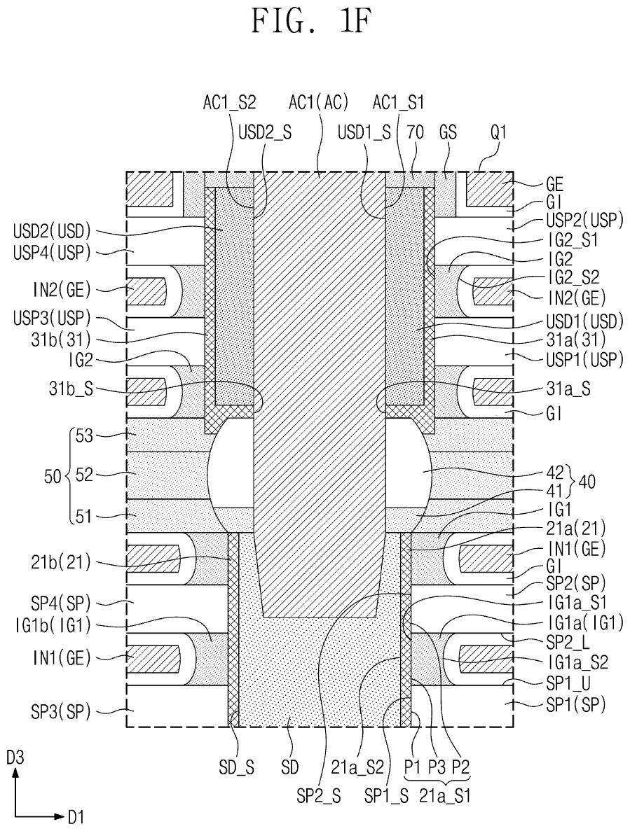

FIG. 1A is a plan view illustrating an example of a semiconductor. FIG. 1B is an example sectional view taken along a line A-A′ of FIG. 1A. FIG. 1C is an example sectional view taken along a line B-B′ of FIG. 1A. FIG. 1D is an example sectional view taken along a line C-C′ of FIG. 1A. FIG. 1E is an example sectional view taken along a line D-D′ of FIG. 1A. FIG. 1F is an example enlarged view illustrating a portion ‘Q1’ of FIG. 1B.

Referring to FIGS. 1A, 1B, 1C, 1D, and 1E, a semiconductor device may include a substrate 10. Logic cells may be disposed on the substrate 10. In the present specification, the logic cell may mean a logic device (e.g., AND, OR, XOR, XNOR, inverter, and so forth) configured to execute a specific function. The logic cell may include transistors constituting the logic device.

The substrate 10 may be a semiconductor substrate, an insulating substrate, or a semiconductor-on-insulator (SOI) substrate. The semiconductor substrate may be formed of or include, for example, silicon, germanium, silicon-germanium, GaP, or GaAs. The substrate 10 may be a plate-shaped structure extended in a first direction D1 and a second direction D2. The first and second directions D1 and D2 may not be parallel to each other. For example, the first and second directions D1 and D2 may be horizontal directions that are orthogonal to each other.

The substrate 10 may include fin patterns FP. The fin patterns FP may be extended in the first direction D1. The fin patterns FP may be arranged in the second direction D2 to be spaced apart from each other. The fin patterns FP may be upper portions of the substrate 10 protruding in a third direction D3. The third direction D3 may not be parallel to the first and second directions D1 and D2. For example, the third direction D3 may be a vertical direction orthogonal to the first and second directions D1 and D2.

In some implementations, a lower portion of the substrate 10 may be omitted, and the fin patterns FP may be spaced apart from each other. In some implementations, the fin patterns FP, which are spaced apart from each other, may include an insulating material.

A device isolation layer 11 may be provided on the substrate 10. The device isolation layer 11 may be provided to enclose the fin patterns FP. The device isolation layer 11 may fill a space between the fin patterns FP. The device isolation layer 11 may include an insulating material. For example, the device isolation layer 11 may include an oxide material. In some implementations, the device isolation layer 11 may be a multi-layered structure including a plurality of insulating layers.

Channel structures CH may be provided. The channel structure CH may be overlapped with the fin pattern FP in the third direction D3. A plurality of channel structures CH, which are overlapped with one of the fin patterns FP in the third direction D3, may be arranged to be spaced apart from each other in the first direction D1. The channel structure CH may include semiconductor patterns SP, which are overlapped with each other in the third direction D3. The semiconductor patterns SP may include a crystalline semiconductor material. The semiconductor patterns SP may include, for example, silicon or silicon-germanium. The number of the semiconductor patterns SP in the channel structure CH may not be limited to the illustrated example. In some implementations, the channel structure CH may include two semiconductor patterns SP or four or more semiconductor patterns SP.

Source/drain patterns SD may be provided. The source/drain pattern SD may be overlapped with the fin pattern FP in the third direction D3. A plurality of source/drain patterns SD, which are overlapped with one of the fin patterns FP in the third direction D3, may be arranged to be spaced apart from each other in the first direction D1. The source/drain pattern SD may be disposed between the channel structures CH. The channel structure CH may be disposed between the source/drain patterns SD.

The source/drain pattern SD may be an epitaxial pattern formed by a selective epitaxial growth (SEG) process. The source/drain pattern SD may be formed of or include silicon or silicon-germanium. The source/drain pattern SD may be doped with impurities. In the case where the source/drain pattern SD includes silicon-germanium, a germanium concentration in the source/drain pattern SD may be uniform throughout the entire region.

Lower patterns LP may be provided. The lower pattern LP may be disposed between the fin pattern FP and the source/drain pattern SD. The lower pattern LP may be overlapped with the fin pattern FP and the source/drain pattern SD in the third direction D3. A plurality of lower patterns LP, which are overlapped with one of the fin patterns FP in the third direction D3, may be arranged to be spaced apart from each other in the first direction D1. The lower pattern LP may include a semiconductor material. In some implementations, the lower pattern LP may include an insulating material. In some implementations, the lower pattern LP may be omitted.

Two-dimensional layers 20 may be provided. The two-dimensional layers 20 may be provided on the fin patterns FP. A plurality of two-dimensional layers 20, which are overlapped with one of the fin patterns FP in the third direction D3, may be arranged to be spaced apart from each other in the first direction D1. The two-dimensional layer 20 may be disposed between the channel structures CH. The two-dimensional layer 20 may be in contact with the fin pattern FP, the lower pattern LP, the source/drain pattern SD, the semiconductor patterns SP, and inner spacers IG1 to be described below. The two-dimensional layer 20 may be provided between the lower pattern LP and the fin pattern FP. The two-dimensional layer 20 may be provided between the semiconductor pattern SP and the source/drain pattern SD. The two-dimensional layer 20 may be provided between the inner spacer IG1 and the source/drain pattern SD. The lower pattern LP and the source/drain pattern SD may be provided on the two-dimensional layer 20.

The two-dimensional layer 20 may include a two-dimensional material. The two-dimensional layer 20 may include a material electrically connecting the semiconductor patterns SP and the source/drain pattern SD, which are placed at both sides of the two-dimensional layer 20, and electrically separating the semiconductor patterns SP, which are overlapped with each other in the third direction D3. In some implementations, the two-dimensional layer 20 may include a two-dimensional insulating material (e.g., h-BN, MnO, MoO, GaSe, GaN, or AsS).

The two-dimensional layer 20 may be a single atomic layer or a multiple atomic layer.

Inner spacers IG1 may be provided. The inner spacer IG1 may be overlapped with the fin pattern FP and the semiconductor pattern SP in the third direction D3. The inner spacers IG1 may include the inner spacers IG1, which are overlapped with each other in the third direction D3. The semiconductor patterns SP may be provided between the inner spacers IG1, which are overlapped with each other in the third direction D3. The inner spacer IG1 may be in contact with the two-dimensional layer 20, the semiconductor pattern SP, and a gate insulating layer GI to be described below. The lowermost one of the inner spacers IG1 may be in contact with the fin pattern FP. The inner spacer IG1 may be disposed between the gate insulating layer GI and the two-dimensional layer 20.

The inner spacer IG1 may include an insulating material. In some implementations, the inner spacer IG1 may include a low-k dielectric material.

Interlayered insulating structures 40 may be provided. The interlayered insulating structure 40 may be provided on the device isolation layer 11, the lower pattern LP, and the source/drain pattern SD. The interlayered insulating structure 40 may include an interlayered liner 41, which is provided on the device isolation layer 11, the lower pattern LP, and the source/drain pattern SD, and an interlayer insulating layer 42, which is provided on the interlayered liner 41. The interlayered liner 41 and the interlayer insulating layer 42 may include an insulating material. In some implementations, the interlayered liner 41 may include a nitride material, and the interlayer insulating layer 42 may include an oxide material.

Upper channel structures UCH may be provided. The upper channel structure UCH may be overlapped with the channel structure CH in the third direction D3. The upper channel structure UCH may include upper semiconductor patterns USP, which are overlapped with each other in the third direction D3. The upper semiconductor patterns USP may include a crystalline semiconductor material. The upper semiconductor patterns USP may include, for example, silicon or silicon-germanium. The number of the upper semiconductor patterns USP in the upper channel structure UCH may not be limited to the illustrated example.

Intervening insulating structures 50 may be provided. The intervening insulating structure 50 may be provided between the upper channel structure UCH and the channel structure CH. The intervening insulating structures 50 and the interlayered insulating structures 40 may be alternately arranged in the first direction D1.

The intervening insulating structure 50 may include a first intervening insulating pattern 51, a second intervening insulating pattern 52 on the first intervening insulating pattern 51, and a third intervening insulating pattern 53 on the second intervening insulating pattern 52. The first to third intervening insulating patterns 51, 52, and 53 may include an insulating material. In some implementations, the first to third intervening insulating patterns 51, 52, and 53 may include a nitride material. In some implementations, the intervening insulating structure 50 may include one insulating pattern.

Upper source/drain patterns USD may be provided. The upper source/drain patterns USD may be overlapped with the fin patterns FP in the third direction D3. A plurality of upper source/drain patterns USD, which are overlapped with one of the fin patterns FP in the third direction D3, may be arranged to be spaced apart from each other in the first direction D1. A pair of upper source/drain patterns USD may be overlapped with the source/drain pattern SD in the third direction D3. In some implementations, the source/drain pattern SD may be disposed between the pair of upper source/drain patterns USD, and the source/drain pattern SD may not be overlapped with the pair of upper source/drain patterns USD in the third direction D3.

A pair of the upper source/drain patterns USD may be disposed between the upper channel structures UCH, which are adjacent to each other in the first direction D1. A pair of the upper source/drain patterns USD may be disposed between the upper semiconductor patterns USP, which are adjacent to each other in the first direction D1. The upper channel structure UCH may be disposed between the upper source/drain patterns USD.

The upper source/drain pattern USD may be an epitaxial pattern formed by a selective epitaxial growth (SEG) process. The upper source/drain pattern USD may include silicon or silicon-germanium. The upper source/drain pattern USD may be doped with impurities. In the case where the upper source/drain pattern USD includes silicon-germanium, a germanium concentration in the upper source/drain pattern USD may be uniform throughout the entire region.

Upper two-dimensional layers 30 may be provided. The upper two-dimensional layer 30 may be provided on the interlayered insulating structure 40. The upper two-dimensional layers 30 may be overlapped with the fin patterns FP in the third direction D3. A plurality of upper two-dimensional layers 30, which are overlapped with one of the fin patterns FP in the third direction D3, may be arranged to be spaced apart from each other in the first direction D1. The upper two-dimensional layer 30 may be overlapped with the two-dimensional layer 20 in the third direction D3. The upper two-dimensional layer 30 may be disposed between the upper channel structures UCH. The upper two-dimensional layer 30 may be in contact with the interlayered insulating structure 40, the upper source/drain pattern USD, the upper semiconductor patterns USP, an active contact AC to be described below, and upper inner spacers IG2 to be described below. The upper two-dimensional layer 30 may be provided between the interlayered insulating structure 40 and the upper source/drain pattern USD. The upper two-dimensional layer 30 may be provided between the upper semiconductor pattern USP and the upper source/drain pattern USD. The upper two-dimensional layer 30 may be provided between the upper inner spacer IG2 and the upper source/drain pattern USD.

The upper two-dimensional layer 30 may include a two-dimensional material. The upper two-dimensional layer 30 may include a material electrically connecting the upper semiconductor patterns USP and the upper source/drain pattern USD, which are placed at both sides of the upper two-dimensional layer 30, and electrically separating the upper semiconductor patterns USP, which are overlapped with each other in the third direction D3. In some implementations, the upper two-dimensional layer 30 may include a two-dimensional insulating material (e.g., h-BN, MnO, MoO, GaSe, GaN, or AsS). The upper two-dimensional layer 30 may be a single atomic layer or a multiple atomic layer.

The two-dimensional layer 20 and the upper two-dimensional layer 30 may include the same two-dimensional material or may include different two-dimensional materials from each other.

The upper inner spacers IG2 may be provided. The upper inner spacer IG2 may be overlapped with the fin pattern FP and the upper semiconductor pattern USP in the third direction D3. The upper inner spacers IG2 may include the upper inner spacers IG2, which are overlapped with each other in the third direction D3. The upper semiconductor pattern USP may be provided between the upper inner spacers IG2, which are overlapped with each other in the third direction D3. The upper inner spacer IG2 may be in contact with the upper two-dimensional layer 30, the upper semiconductor pattern USP, and the gate insulating layer GI. The lowermost one of the upper inner spacers IG2 may be in contact with the intervening insulating structure 50. The upper inner spacer IG2 may be disposed between the gate insulating layer GI and the upper two-dimensional layer 30.

The upper inner spacer IG2 may include an insulating material. In some implementations, the upper inner spacer IG2 may include a low-k dielectric material.

Gate electrodes GE may be provided to extend in the second direction D2. The gate electrode GE may be provided to cross the channel structure CH and the upper channel structure UCH. The gate electrode GE may be overlapped with the channel structure CH and the upper channel structure UCH in the third direction D3. The gate electrode GE may be arranged in the first direction D1 to be spaced apart from each other. The source/drain pattern SD may be disposed between the gate electrodes GE. The upper source/drain patterns USD may be disposed between the gate electrodes GE.

The gate electrode GE may include first electrode portions IN1 and second electrode portions IN2. The first electrode portion IN1 may be disposed between the semiconductor patterns SP, between the semiconductor pattern SP and the fin pattern FP, or between the semiconductor pattern SP and the intervening insulating structure 50. The second electrode portion IN2 may be disposed between the upper semiconductor patterns USP or between the upper semiconductor pattern USP and the intervening insulating structure 50. The inner spacer IG1 may be provided between the first electrode portion IN1 and the two-dimensional layer 20. The upper inner spacer IG2 may be provided between the second electrode portion IN2 and the upper two-dimensional layer 30.

The gate electrode GE may include a conductive material. The gate electrode GE may be provided to enclose the semiconductor patterns SP and the upper semiconductor patterns USP (e.g., when viewed in the sectional view of FIG. 1E). The gate electrode GE, the semiconductor patterns SP, and the upper semiconductor patterns USP may constitute a three-dimensional field effect transistor (e.g., MBCFET or GAAFET).

The gate insulating layers GI may be provided. The gate insulating layer GI may be in contact with the gate electrode GE. The gate insulating layer GI may separate the gate electrode GE from the semiconductor patterns SP and the upper semiconductor patterns USP. The gate insulating layer GI may be provided to enclose the semiconductor patterns SP, the upper semiconductor patterns USP, and the intervening insulating structure 50 (e.g., in a sectional view of FIG. 1E). The gate insulating layer GI may be in contact with an inner spacer GII and the upper inner spacer IG2. The gate insulating layer GI may include an insulating material. In some implementations, the gate insulating layer GI may include an oxide material.

Gate spacers GS may be provided. A pair of the gate spacers GS may be provided at both sides of the gate electrode GE. The gate spacers GS may be extended in the second direction D2. The gate spacers GS may include an insulating material.

A gate capping pattern GP may be provided. The gate capping pattern GP may be provided on the gate electrode GE. The gate capping pattern GP may be extended in the second direction D2. The gate capping pattern GP may be disposed between the gate spacers GS. The gate capping pattern GP may include an insulating material.

A cover liner 70 may be provided. The cover liner 70 may be provided on the gate spacer GS and the upper source/drain pattern USD. The cover liner 70 may include an insulating material.

A cover insulating layer 60 may be provided on the cover liner 70. The cover insulating layer 60 may include an insulating material.

The active contacts AC may be provided. The active contact AC may be electrically connected to two upper source/drain patterns USD and one source/drain pattern SD. The active contact AC may be in contact with two upper source/drain patterns USD and one source/drain pattern SD. The active contact AC may be provided to penetrate the cover insulating layer 60, the cover liner 70, and the interlayered insulating structure 40. The active contact AC may include a conductive material.

Gate contacts may be provided. The gate contact may be electrically connected to the gate electrode GE. The gate contact may include a conductive material.

Gate division layers 65 may be provided. The gate division layers 65 may be provided on the device isolation layer 11. The gate electrode GE may be provided between the gate division layers 65. The gate electrodes GE may be spaced apart from each other by the gate division layer 65. The gate division layer 65 may include an insulating material.

Referring to FIG. 1F, the semiconductor patterns SP may include a first semiconductor pattern SP1 and a second semiconductor pattern SP2, which are overlapped with each other in the third direction D3, and a third semiconductor pattern SP3 and a fourth semiconductor pattern SP4, which are overlapped with each other in the third direction D3. The second and fourth semiconductor patterns SP2 and SP4 may be disposed at a level (e.g., a vertical level from the top surface of the substrate 10), which is higher than the first and third semiconductor patterns SP1 and SP3. The first and third semiconductor patterns SP1 and SP3 may be adjacent to each other in the first direction D1. The second and fourth semiconductor patterns SP2 and SP4 may be adjacent to each other in the first direction D1.

The first electrode portions IN1 may be provided between the first semiconductor pattern SP1 and the second semiconductor pattern SP2. The inner spacers IG1 may include a first inner spacer IG1a, which is provided between the first semiconductor pattern SP1 and the second semiconductor pattern SP2, and a second inner spacer IG1b, which is provided between the third semiconductor pattern SP3 and the fourth semiconductor pattern SP4.

The first inner spacer IG1a may be in contact with a top surface SP1_U of the first semiconductor pattern SP1 and a bottom surface SP2_L of the second semiconductor pattern SP2. A top surface of the first inner spacer IG1a may be in contact with the bottom surface SP2_L of the second semiconductor pattern SP2. A bottom surface of the first inner spacer IG1a may be in contact with the top surface SP1_U of the first semiconductor pattern SP1.

The second inner spacer IG1b may be in contact with a top surface of the third semiconductor pattern SP3 and a bottom surface of the fourth semiconductor pattern SP4. A top surface of the second inner spacer IG1b may be in contact with the bottom surface of the fourth semiconductor pattern SP4. A bottom surface of the second inner spacer IG1b may be in contact with the top surface of the third semiconductor pattern SP3.

The two-dimensional layers 20 may include a first two-dimensional layer 21 between the first and third semiconductor patterns SP1 and SP3 and between the second and fourth semiconductor patterns SP2 and SP4. The first two-dimensional layer 21 may include a first portion 21a, which is in contact with the first semiconductor pattern SP1, the first inner spacer IG1a, and the second semiconductor pattern SP2, and a second portion 21b, which is in contact with the third semiconductor pattern SP3, the second inner spacer IG1b, and the fourth semiconductor pattern SP4.

An outer side surface 21a_S1 of the first portion 21a of the first two-dimensional layer 21 may include a first portion P1 in contact with a side surface SP1_S of the first semiconductor pattern SP1, a second portion P2 in contact with a side surface SP2_S of the second semiconductor pattern SP2, and a third portion P3 in contact with a first side surface IG1a_S1 of the first inner spacer IG1a.

An inner side surface 21a_S2 of the first portion 21a of the first two-dimensional layer 21 may be in contact with a side surface SD_S of the source/drain pattern SD. The side surface SD_S of the source/drain pattern SD may be flat.

The first to third portions P1, P2, and P3 of the outer side surface 21a_S1 of the first portion 21a of the first two-dimensional layer 21 may be placed on a straight line extending in the third direction D3. The first to third portions P1, P2, and P3 of the outer side surface 21a_S1 of the first portion 21a of the first two-dimensional layer 21 may be overlapped with each other in the third direction D3. The first to third portions P1, P2, and P3 of the outer side surface 21a_S1 of the first portion 21a of the first two-dimensional layer 21 may be coplanar with each other. The first to third portions P1, P2, and P3 of the outer side surface 21a_S1 of the first portion 21a of the first two-dimensional layer 21 may be flat.

A thickness of the first portion 21a of the first two-dimensional layer 21 in the first direction D1 may be constant. In some implementations, a thickness of the first portion 21a of the first two-dimensional layer 21 in the first direction D1 may be less than or equal to 9 Å. A distance between the inner and outer side surfaces 21a_S2 and 21a_S1 of the first portion 21a of the first two-dimensional layer 21 in the first direction D1 may be constant. The inner and outer side surfaces 21a_S2 and 21a_S1 of the first portion 21a of the first two-dimensional layer 21 may be flat.

The side surface SP1_S of the first semiconductor pattern SP1, the side surface SP2_S of the second semiconductor pattern SP2, and the first side surface IG1a_S1 of the first inner spacer IG1a may be placed on a straight line extending in the third direction D3. The side surface SP1_S of the first semiconductor pattern SP1, the side surface SP2_S of the second semiconductor pattern SP2, and the first side surface IG1a_S1 of the first inner spacer IG1a may be overlapped with each other in the third direction D3. The side surface SP1_S of the first semiconductor pattern SP1, the side surface SP2_S of the second semiconductor pattern SP2, and the first side surface IG1a_S1 of the first inner spacer IG1a may be coplanar with each other. The side surface SP1_S of the first semiconductor pattern SP1, the side surface SP2_S of the second semiconductor pattern SP2, and the first side surface IG1a_S1 of the first inner spacer IG1a may be flat.

The first inner spacer IG1a may include a second side surface IG1a_S2, which is opposite to the first side surface IG1a_S1 of the first inner spacer IG1a. The second side surface IG1a_S2 of the first inner spacer IG1a may be bent (for example, including a curved shape). The second side surface IG1a_S2 of the first inner spacer IG1a may be in contact with the gate insulating layer GI. The gate insulating layer GI may be provided between the second side surface IG1a_S2 of the first inner spacer IG1a and the first electrode portion IN1.

Since the second side surface IG1a_S2 of the first inner spacer IG1a is bent and the first side surface IG1a_S1 of the first inner spacer IG1a is flat, an area of the first side surface IG1a_S1 of the first inner spacer IG1a may be smaller than an area of the second side surface IG1a_S2 of the first inner spacer IG1a. A length of the first side surface IG1a_S1 of the first inner spacer IG1a in the second direction D2 may be equal to a length of the second side surface IG1a_S2 of the first inner spacer IG1a in the second direction D2.

The upper semiconductor patterns USP may include a first upper semiconductor pattern USP1 and a second upper semiconductor pattern USP2, which are overlapped with each other in the third direction D3, and a third upper semiconductor pattern USP3 and a fourth upper semiconductor pattern USP4, which are overlapped with each other in the third direction D3. The second and fourth upper semiconductor patterns USP2 and USP4 may be placed at a level higher than the first and third upper semiconductor patterns USP1 and USP3. The first and third upper semiconductor patterns USP1 and USP3 may be adjacent to each other in the first direction D1. The second and fourth upper semiconductor patterns USP2 and USP4 may be adjacent to each other in the first direction D1. The first and second upper semiconductor patterns USP1 and USP2 may be overlapped with the first and second semiconductor patterns SP1 and SP2 in the third direction D3. The third and fourth upper semiconductor patterns USP3 and USP4 may be overlapped with the third and fourth semiconductor patterns SP3 and SP4 in the third direction D3.

The second electrode portions IN2 may be provided between the first and second upper semiconductor patterns USP1 and USP2. The upper inner spacers IG2 may be provided between the first and second upper semiconductor patterns USP1 and USP2.

The upper two-dimensional layers 30 may include a first upper two-dimensional layer 31 between the first and third upper semiconductor patterns USP1 and USP3 and between the second and fourth upper semiconductor patterns USP2 and USP4. The first upper two-dimensional layer 31 may include a first portion 31a, which is in contact with the first upper semiconductor pattern USP1, the upper inner spacer IG2, and the second upper semiconductor pattern USP2, and a second portion 31b, which is in contact with the third upper semiconductor pattern USP3, the upper inner spacer IG2, and the fourth upper semiconductor pattern USP4.

A first active contact AC1 may be provided between the first and second portions 31a and 31b of the first upper two-dimensional layer 31. The upper source/drain patterns USD may include a first upper source/drain pattern USD1, which is provided between the first portion 31a of the first upper two-dimensional layer 31 and the first active contact AC1, and a second upper source/drain pattern USD2, which is provided between the second portion 31b of the first upper two-dimensional layer 31 and the first active contact AC1.

The first active contact AC1 may include a first side surface AC1_S1 and a second side surface AC1_S2, which are opposite to each other. The first side surface AC1_S1 of the first active contact AC1 may be in contact with a side surface USD1_S of the first upper source/drain pattern USD1 and a surface 31a_S of the first portion 31a of the first upper two-dimensional layer 31. The second side surface AC1_S2 of the first active contact AC1 may be in contact with a side surface USD2_S of the second upper source/drain pattern USD2 and a surface 31b_S of the second portion 31b of the first upper two-dimensional layer 31. The first active contact AC1 may be provided to penetrate the first upper two-dimensional layer 31. In some implementations, the first and second portions 31a and 31b of the first upper two-dimensional layer 31 may be separated from each other by the first active contact AC1.

The side surface USD1_S of the first upper source/drain pattern USD1 and the surface 31a_S of the first portion 31a of the first upper two-dimensional layer 31 may be coplanar with each other. The side surface USD2_S of the second upper source/drain pattern USD2 and the surface 31b_S of the second portion 31b of the first upper two-dimensional layer 31 may be coplanar with each other.

A distance between the first and second portions 31a and 31b of the first upper two-dimensional layer 31 in the first direction D1 may be larger than a distance between the first and second portions 21a and 21b of the first two-dimensional layer 21 in the first direction D1.

A portion of the first upper source/drain pattern USD1 and a portion of the second upper source/drain pattern USD2 may be overlapped with the source/drain pattern SD in the third direction D3. In some implementations, the first and second upper source/drain patterns USD1 and USD2 may not be overlapped with a portion of the source/drain pattern SD therebetween in the third direction D3.

A side surface of the first upper semiconductor pattern USP1, a side surface of the second upper semiconductor pattern USP2, and a first side surface IG2_S1 of the upper inner spacer IG2 may be coplanar with each other. The side surface of the first upper semiconductor pattern USP1, the side surface of the second upper semiconductor pattern USP2, and the first side surface IG2_S1 of the upper inner spacer IG2 may be flat.

The upper inner spacer IG2 may include a second side surface IG2_S2, which is opposite to the first side surface IG2_S1 of the upper inner spacer IG2. The second side surface IG2_S2 of the upper inner spacer IG2 may be bent. The second side surface IG2_S2 of the upper inner spacer IG2 may be in contact with the gate insulating layer GI. The gate insulating layer GI may be provided between the second side surface IG2_S2 of the upper inner spacer IG2 and the second electrode portion IN2.

Since the second side surface IG2_S2 of the upper inner spacer IG2 is bent and the first side surface IG2_S1 of the upper inner spacer IG2 is flat, an area of the second side surface IG2_S2 of the upper inner spacer IG2 may be larger than an area of the first side surface IG2_S1 of the upper inner spacer IG2.

In some implementations, since the semiconductor device includes the two-dimensional layer 20 and the upper two-dimensional layer 30, the inner spacer IG1 and the upper inner spacer IG2 may have a flat side surface. Accordingly, the inner spacer IG1 and the upper inner spacer IG2 including the low-k dielectric material may be provided to have a relatively large width, and thus, a capacitance between the gate electrode GE and the source/drain pattern SD and between the gate electrode GE and the upper source/drain pattern USD may be reduced.

In the semiconductor device according to some implementations, since each of the inner spacer IG1 and the upper inner spacer IG2 has a side surface having a relatively small area and a flat shape, the capacitance may be reduced.

In the semiconductor device according to some implementations, since the two-dimensional layer 20 and the upper two-dimensional layer 30 are provided, it may be unnecessary to provide a plurality of layers with different germanium concentrations in each of the source/drain pattern SD and the upper source/drain pattern USD. Accordingly, each of the source/drain pattern SD and the upper source/drain pattern USD may have a uniform germanium concentration throughout the entire region, and thus, the performance of the semiconductor device may be improved.

In the semiconductor device according to some implementations, a germanium concentration in the source/drain pattern SD and the upper source/drain pattern USD may be relatively high, and this may make it possible to increase a stress exerted on the semiconductor pattern SP and the upper semiconductor pattern USP and thereby to increase the mobility of electron.

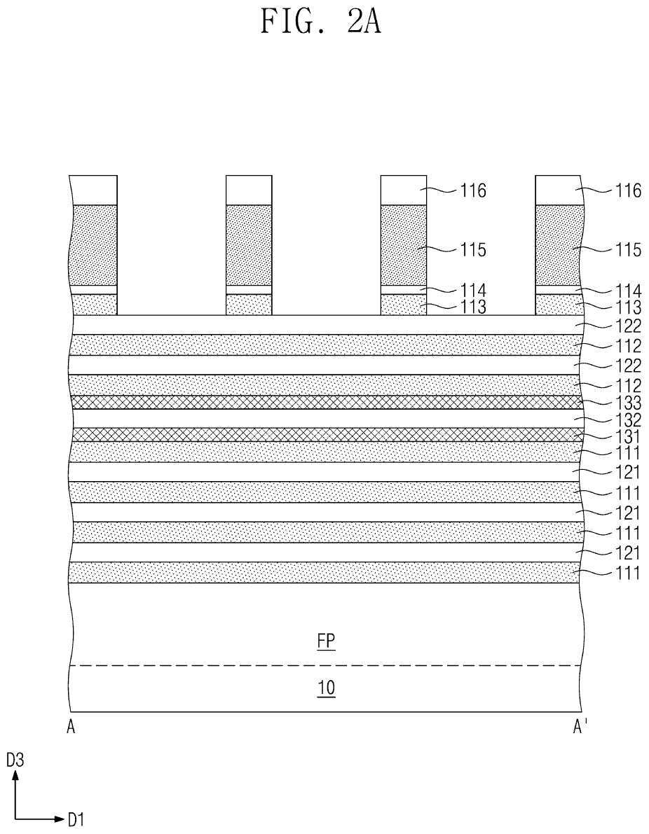

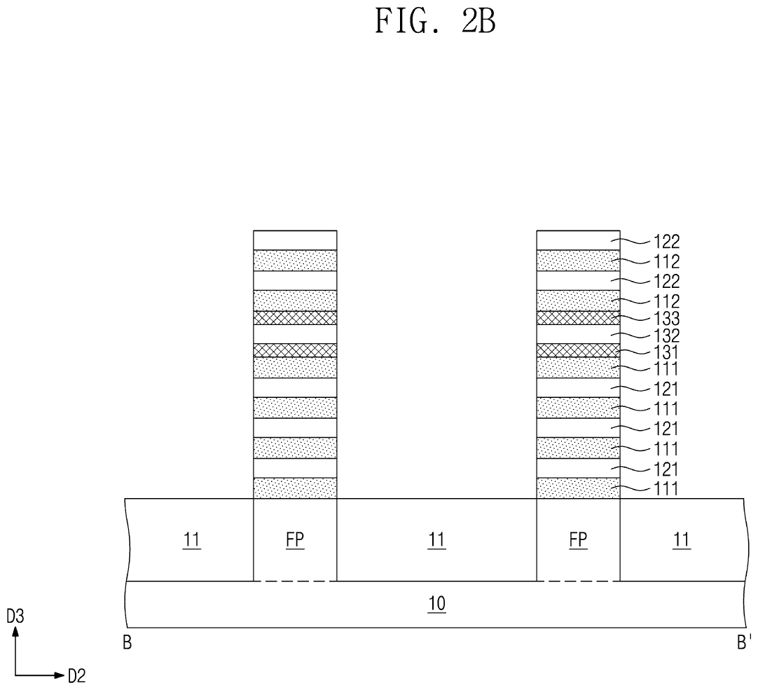

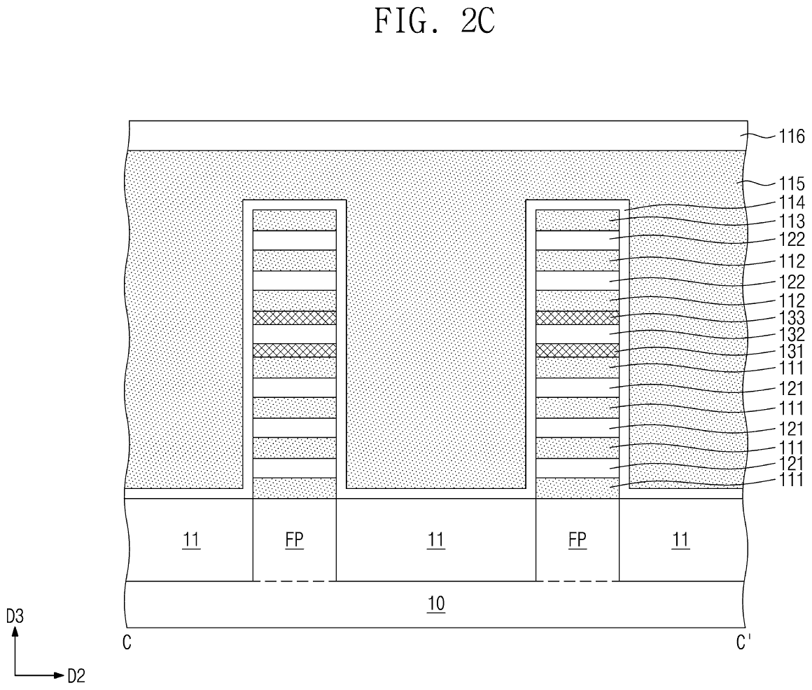

FIGS. 2A, 2B, 2C, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16, 17, 18A, 18B, 19A, 19B, 20A, 20B, 21A, and 21B are diagrams illustrating an example of a method of fabricating the semiconductor device of FIGS. 1A to 1F.

Referring to FIGS. 2A, 2B, and 2C, the substrate 10 may be provided. The fin patterns FP, first sacrificial layers 111, first semiconductor layers 121, first interlayer patterns 131, second interlayer patterns 132, third interlayer patterns 133, second sacrificial layers 112, second semiconductor layers 122, third sacrificial layers 113, sacrificial insulating layers 114, sacrificial patterns 115, and mask patterns 116 may be formed.

In some implementations, the fin patterns FP, the first sacrificial layers 111, the first semiconductor layers 121, the first interlayer patterns 131, the second interlayer patterns 132, the third interlayer patterns 133, the second sacrificial layers 112, the second semiconductor layers 122, the third sacrificial layers 113, the sacrificial insulating layers 114, and the sacrificial patterns 115 may be formed by an etching process using the mask patterns 116 as an etch mask.

The first to third sacrificial layers 111, 112, and 113 may include a first semiconductor material. The first and second semiconductor layers 121 and 122 and the second interlayer pattern 132 may include a second semiconductor material. The first and third interlayer patterns 131 and 133 may include a third semiconductor material.

The first semiconductor material may have an etch selectivity with respect to the second and third semiconductor materials. The second semiconductor material may have an etch selectivity with respect to the third semiconductor material. In some implementations, the second semiconductor material may include silicon, the first and third semiconductor materials may include silicon-germanium, and a germanium concentration of the first semiconductor material may be lower than a germanium concentration of the third semiconductor material.

The sacrificial insulating layers 114 and the mask patterns 116 may include an insulating material. The sacrificial patterns 115 may include, for example, poly silicon. The device isolation layer 11 may be formed.

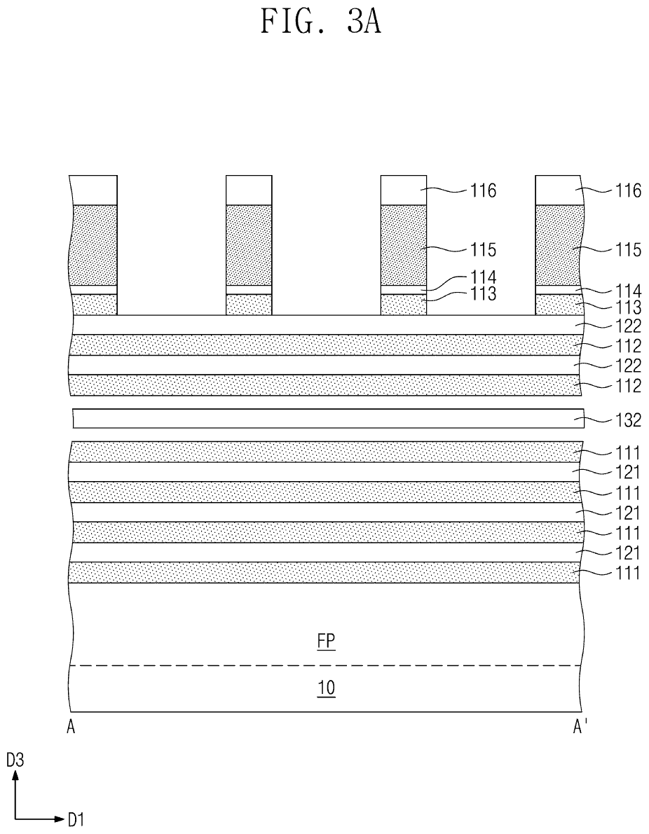

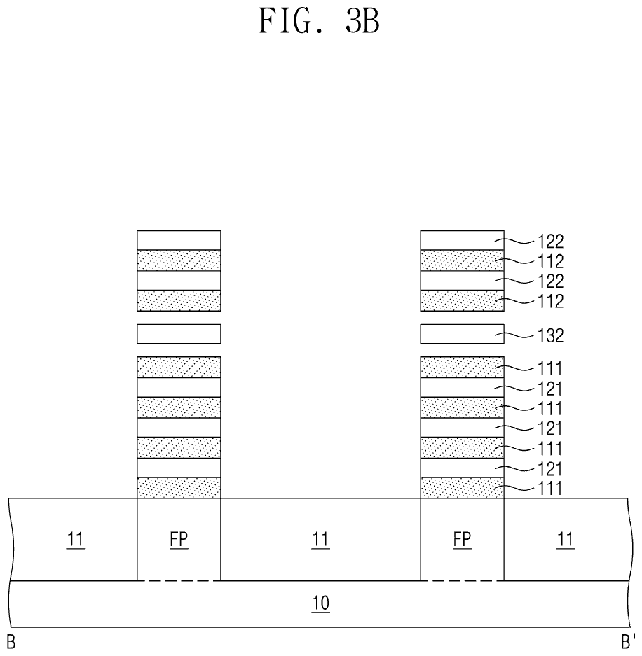

Referring to FIGS. 3A and 3B, the first interlayer patterns 131 and the third interlayer patterns 133 may be selectively removed.

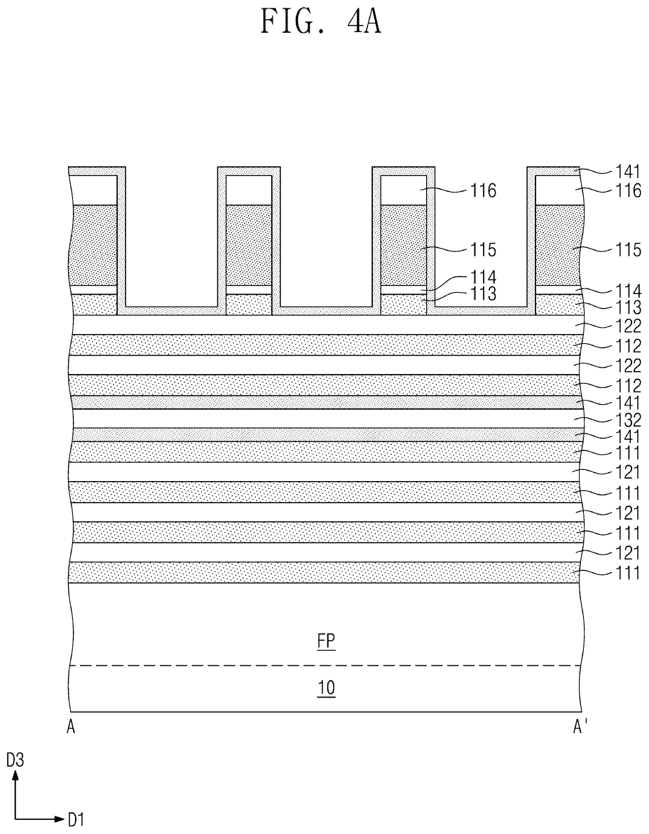

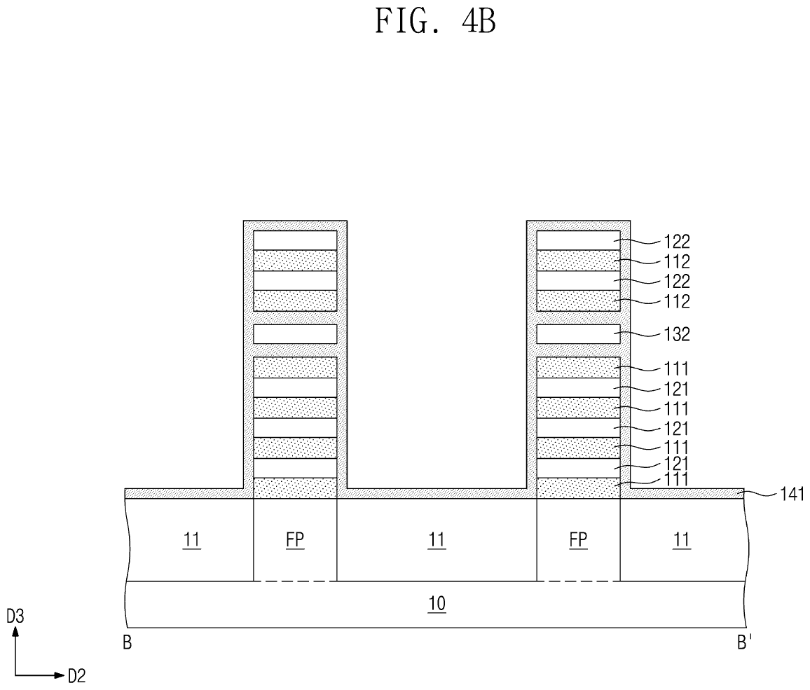

Referring to FIGS. 4A and 4B, a first preliminary insulating layer 141 may be formed. The first preliminary insulating layer 141 may be formed by, for example, a deposition process. The first preliminary insulating layer 141 may cover the first sacrificial layers 111, the first semiconductor layers 121, the second interlayer patterns 132, the second sacrificial layers 112, the second semiconductor layers 122, the third sacrificial layers 113, the sacrificial insulating layers 114, the sacrificial patterns 115, and the mask patterns 116. The first preliminary insulating layer 141 may fill empty spaces, which are formed by removing the first interlayer patterns 131 and the third interlayer patterns 133. The first preliminary insulating layer 141 may include an insulating material. In some implementations, the first preliminary insulating layer 141 may be formed of or include nitride.

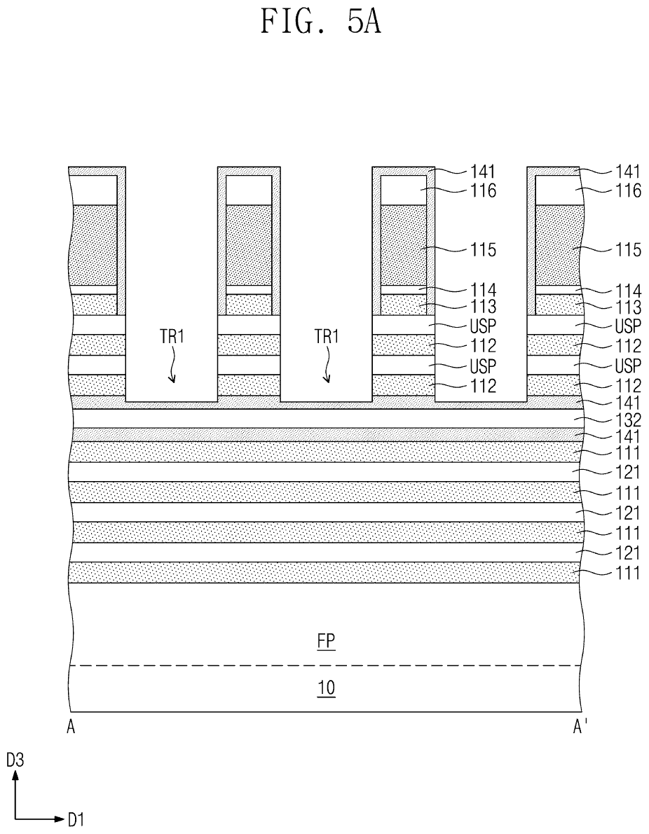

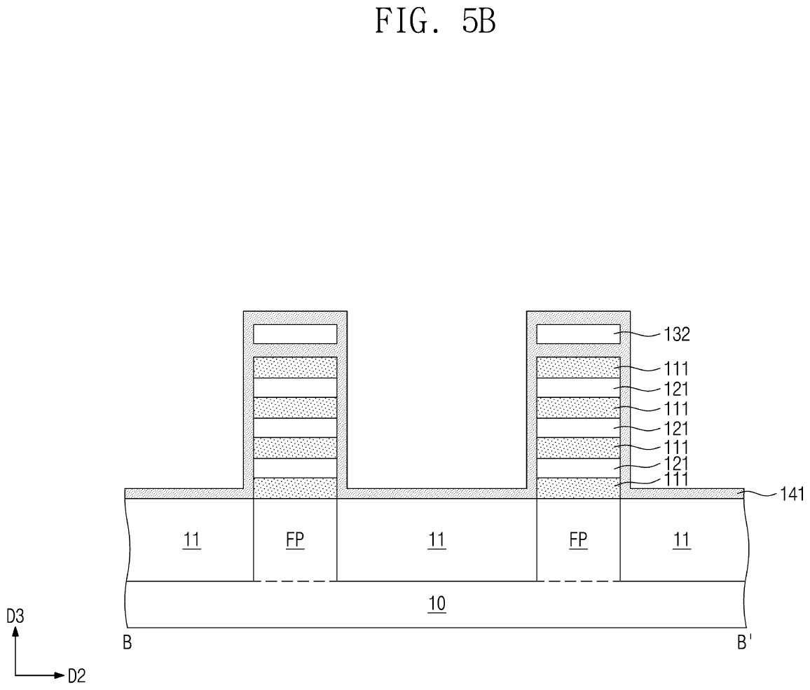

Referring to FIGS. 5A and 5B, the first preliminary insulating layer 141, the second semiconductor layers 122, and the second sacrificial layers 112 may be etched. For example, the first preliminary insulating layer 141, the second semiconductor layers 122, and the second sacrificial layers 112 may be etched by an anisotropic etching process.

The upper semiconductor patterns USP may be formed by the etching of the second semiconductor layer 122. The second semiconductor layer 122 may be divided into the upper semiconductor patterns USP.

As a result of the etching of the second semiconductor layers 122 and the second sacrificial layers 112, first trenches TR1 may be formed. The first trench TR1 may be an empty space between the upper semiconductor patterns USP and between the second sacrificial layers 112.

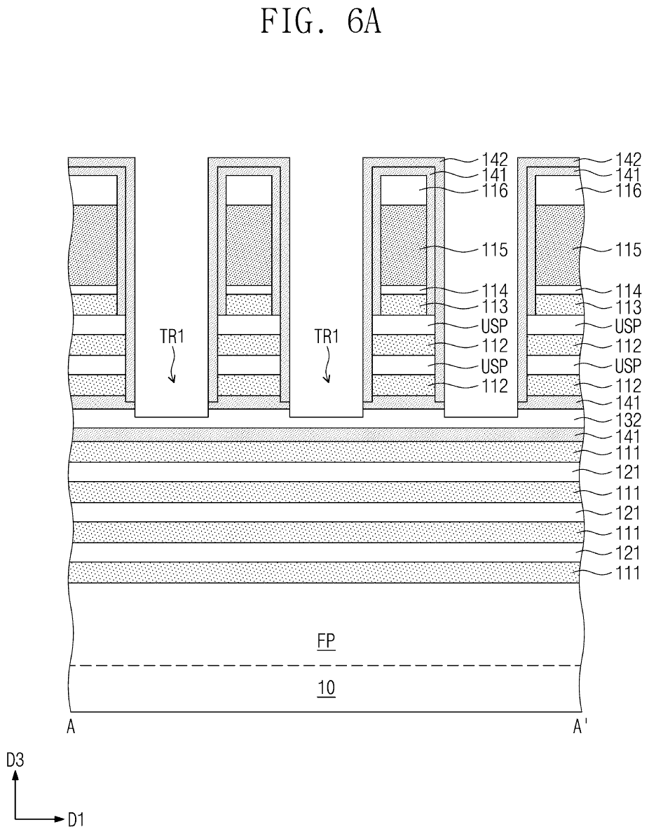

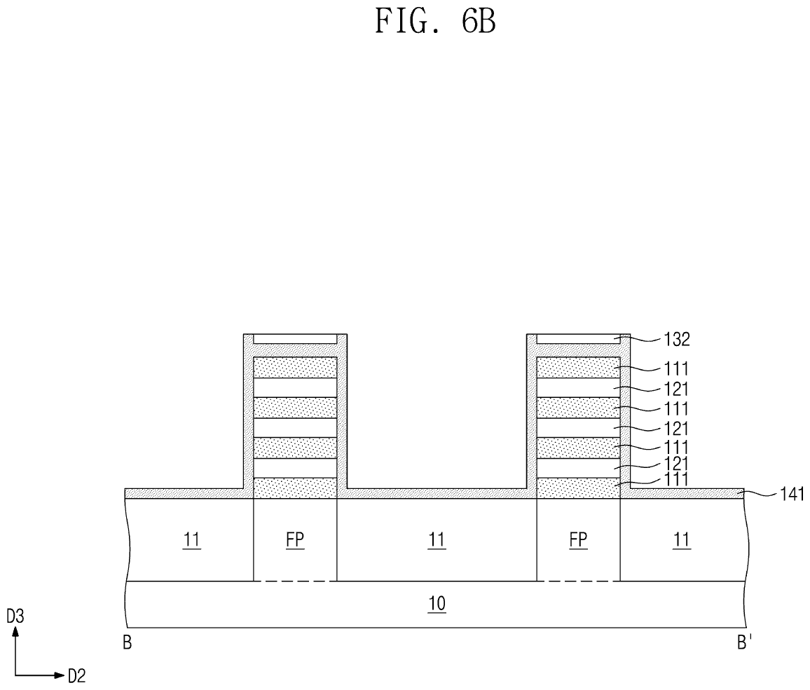

Referring to FIGS. 6A and 6B, a second preliminary insulating layer 142 may be formed. The second preliminary insulating layer 142 may include an insulating material. In some implementations, the second preliminary insulating layer 142 may be formed of or include nitride. A portion of the second preliminary insulating layer 142 may be provided in the first trench TR1. The second preliminary insulating layer 142 may cover the first preliminary insulating layer 141, the upper semiconductor pattern USP, and the second sacrificial layer 112.

The second preliminary insulating layer 142, the first preliminary insulating layer 141, and the second interlayer patterns 132 may be etched through the first trenches TR1. In some implementations, the second preliminary insulating layer 142, the first preliminary insulating layer 141, and the second interlayer patterns 132 may be etched by an anisotropic etching process. As a result of the etching of the second preliminary insulating layer 142, the first preliminary insulating layer 141, and the second interlayer patterns 132, the first trenches TR1 may be enlarged.

As a result of the etching of the first preliminary insulating layer 141, the second interlayer patterns 132 may be exposed through the first trenches TR1.

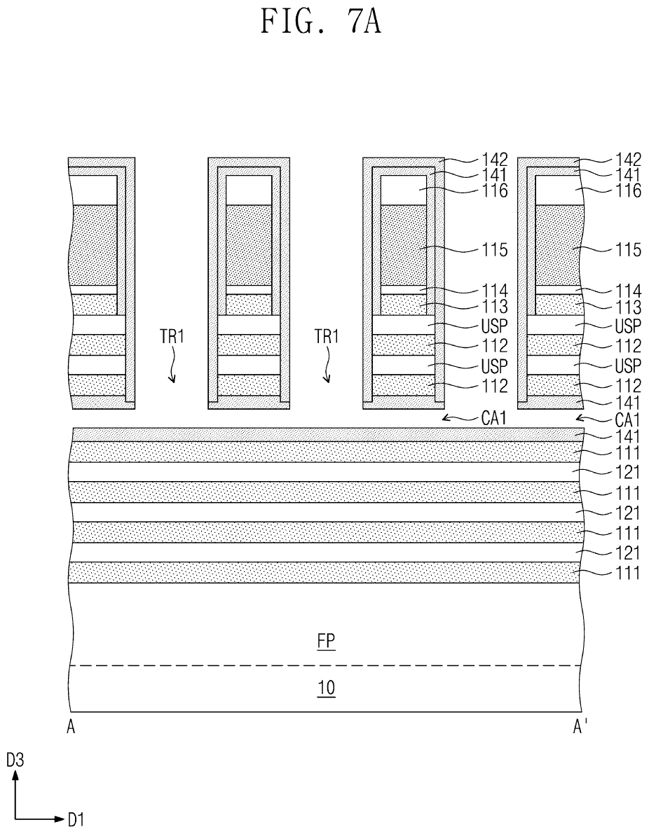

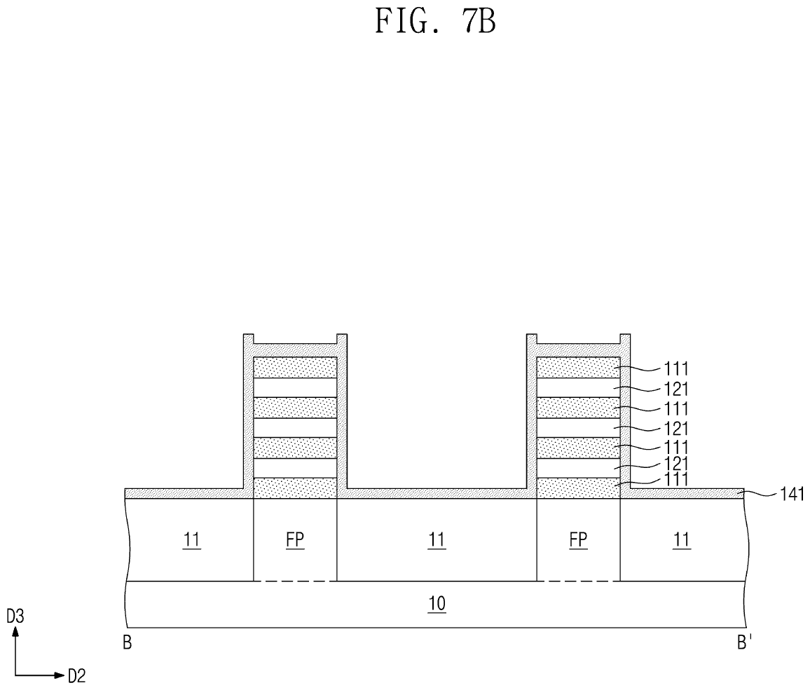

Referring to FIGS. 7A and 7B, the second interlayer patterns 132, which are exposed through the first trenches TR1, may be removed. Empty spaces, which are formed by removing the second interlayer patterns 132, may be defined as first cavities CA1. The first cavity CA1 may be disposed between the first and second sacrificial layers 111 and 112. The first cavity CA1 may be disposed between the first semiconductor layer 121 and the upper semiconductor pattern USP. The first cavity CA1 may be connected to the first trench TR1. The first trenches TR1 may be enlarged as a result of the removal of the second interlayer patterns 132.

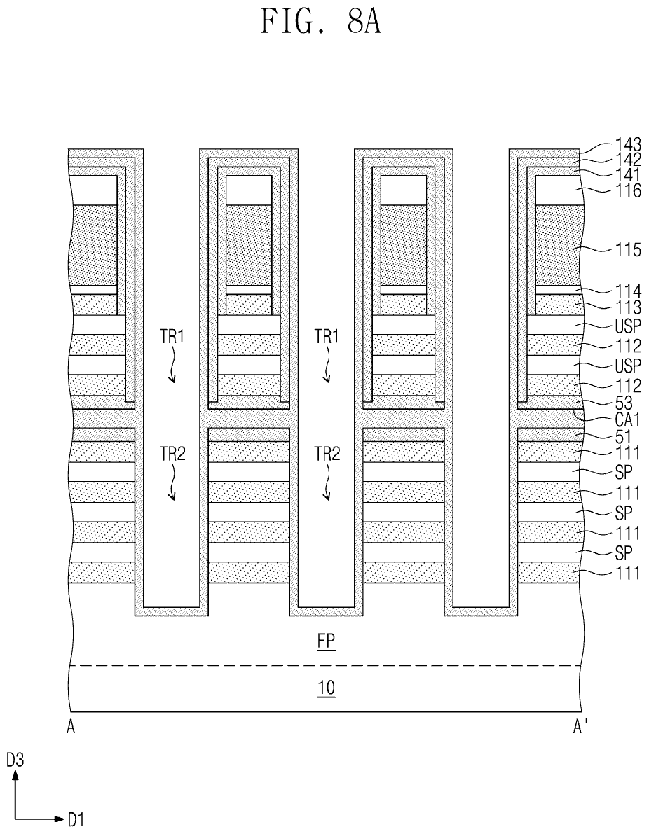

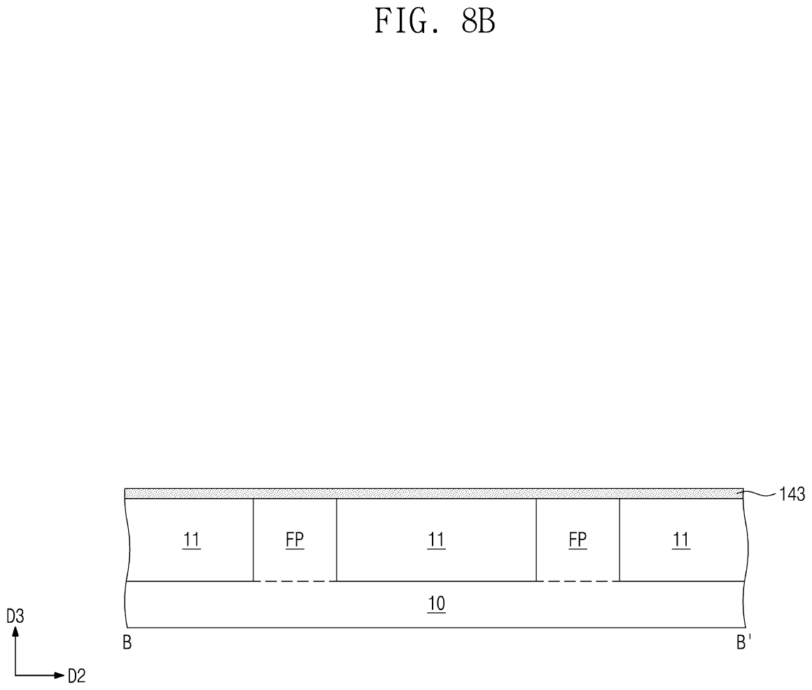

Referring to FIGS. 8A and 8B, the first preliminary insulating layer 141, the first sacrificial layers 111, the first semiconductor layers 121, and the fin patterns FP may be etched through the first trenches TR1. For example, the first preliminary insulating layer 141, the first sacrificial layers 111, the first semiconductor layers 121, and the fin patterns FP may be formed by an anisotropic etching process.

As a result of the etching of the first semiconductor layer 121, the semiconductor patterns SP may be formed. For example, the first semiconductor layer 121 may be divided into the semiconductor patterns SP separated from each other.

As a result of the etching of the first semiconductor layers 121 and the first sacrificial layers 111, second trenches TR2 may be formed. The second trench TR2 may be an empty space between the semiconductor patterns SP and between the first sacrificial layers 111. The second trench TR2 may be connected to the first trench TR1. The second trench TR2 may be overlapped with the first trench TR1 in the third direction D3.

The first and third intervening insulating patterns 51 and 53 may be defined. The first and third intervening insulating patterns 51 and 53 may be portions of the first preliminary insulating layer 141 which are separated from each other.

A third preliminary insulating layer 143 may be formed. The third preliminary insulating layer 143 may include an insulating material. In some implementations, the third preliminary insulating layer 143 may include a nitride material. The third preliminary insulating layer 143 may cover the second preliminary insulating layer 142, the first sacrificial layer 111, the semiconductor pattern SP, the fin pattern FP, the first intervening insulating pattern 51, and the third intervening insulating pattern 53.

The third preliminary insulating layer 143 may fill the first cavities CA1. The third preliminary insulating layer 143 may include a portion in the first trench TR1 and a portion in the second trench TR2.

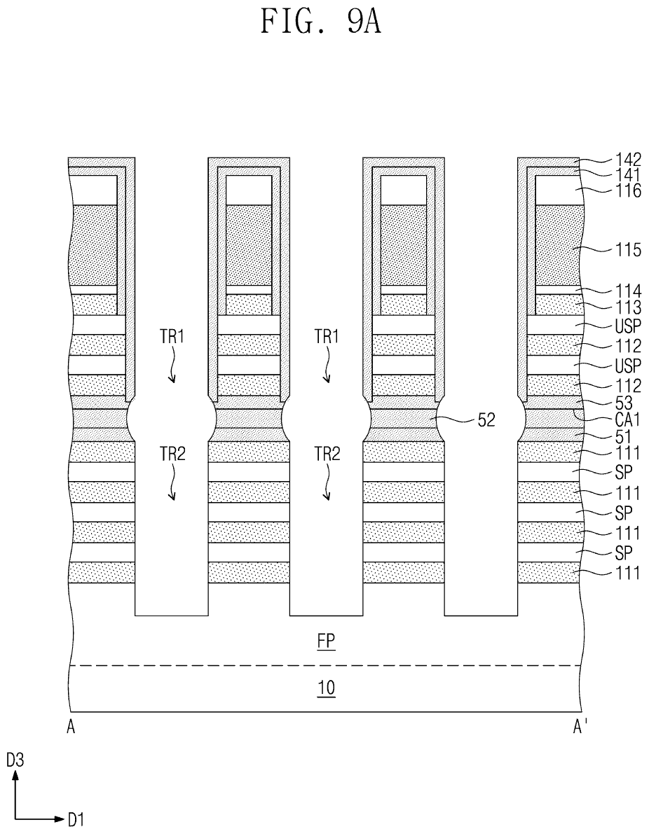

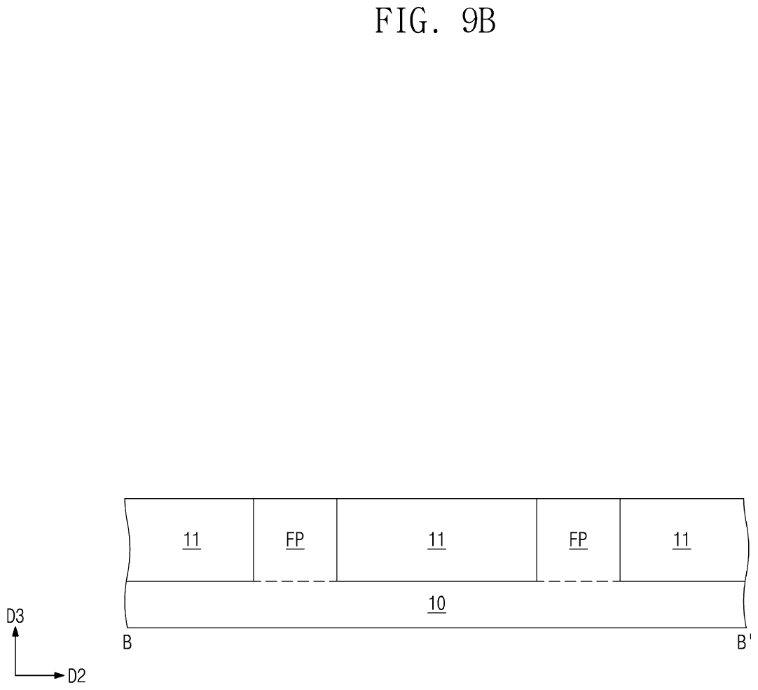

Referring to FIGS. 9A and 9B, the third preliminary insulating layer 143 may be etched. In some implementations, the etching of the third preliminary insulating layer 143 may be performed to expose the fin patterns FP, the first sacrificial layers 111, the semiconductor patterns SP, the first intervening insulating patterns 51, the third intervening insulating patterns 53, and the second preliminary insulating layer 142.

The second intervening insulating patterns 52 may be defined. The second intervening insulating pattern 52 may be a portion of the third preliminary insulating layer 143 left in the first cavity CA1.

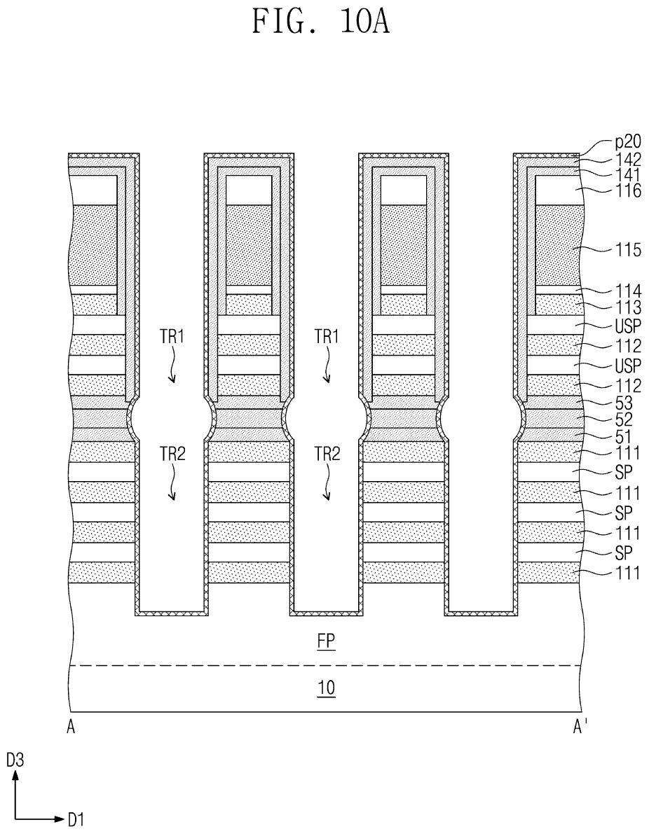

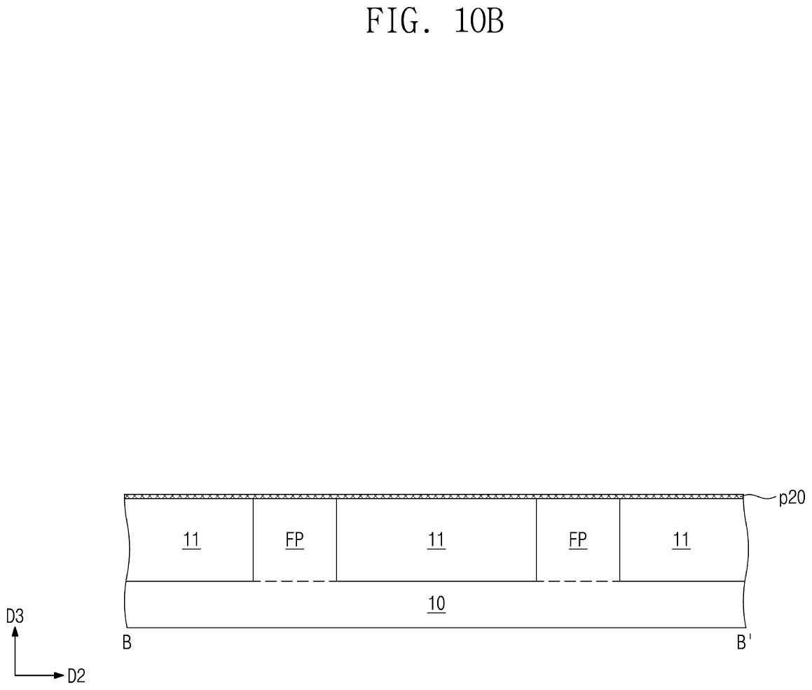

Referring to FIGS. 10A and 10B, a first preliminary two-dimensional layer p20 may be formed. For example, the first preliminary two-dimensional layer p20 may be formed by an atomic layer deposition (ALD) process. The first preliminary two-dimensional layer p20 may include a two-dimensional material.

The first preliminary two-dimensional layer p20 may include a portion, which is formed in the first trench TR1, and a portion, which is formed in the second trench TR2. The first preliminary two-dimensional layer p20 may be formed on the fin pattern FP, the first sacrificial layer 111, the semiconductor pattern SP, the first to third intervening insulating patterns 51, 52, and 53, and the second preliminary insulating layer 142.

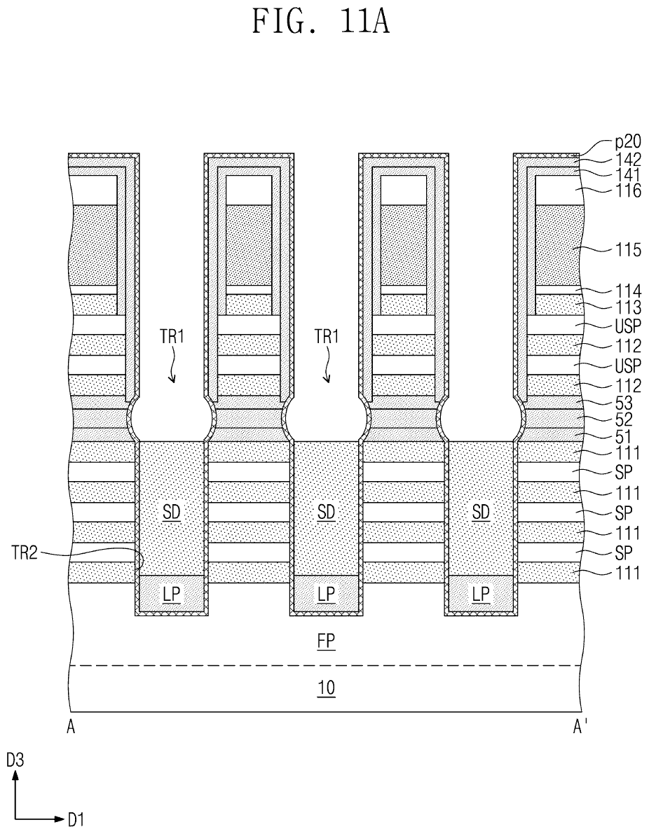

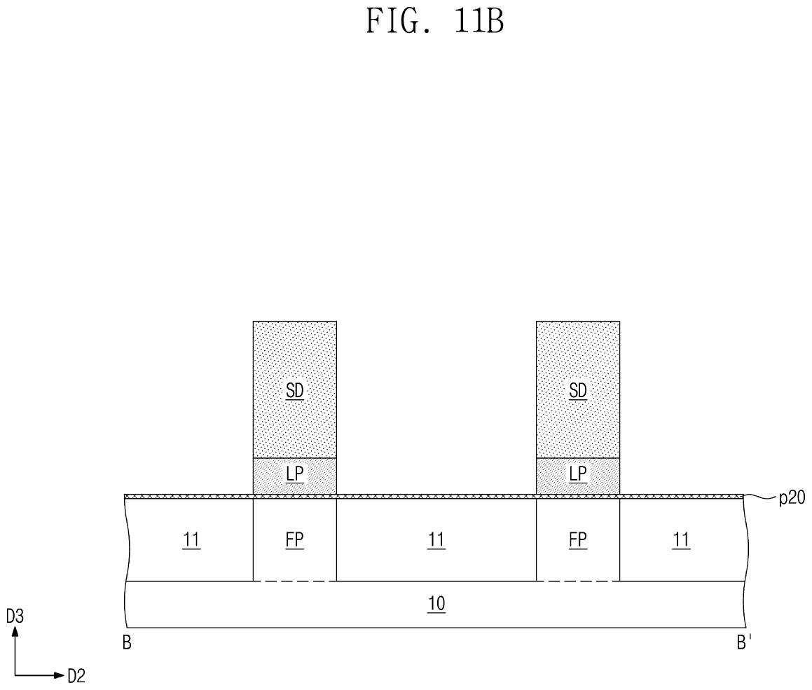

Referring to FIGS. 11A and 11B, the lower patterns LP and the source/drain patterns SD may be formed. For example, the lower patterns LP and the source/drain patterns SD may be formed by an epitaxial growth process using the semiconductor pattern SP and the first sacrificial layer 111 as a seed layer.

In some implementations, the first preliminary two-dimensional layer p20 may have a relatively small thickness, and in this case, the lower pattern LP and the source/drain pattern SD may be formed through a remote epitaxial growth process, in which the semiconductor pattern SP and the first sacrificial layer 111 are used as a seed layer. In some implementations, a thickness of the first preliminary two-dimensional layer p20 may be less than or equal to 9 Å.

The lower pattern LP and the source/drain pattern SD may fill the second trench TR2.

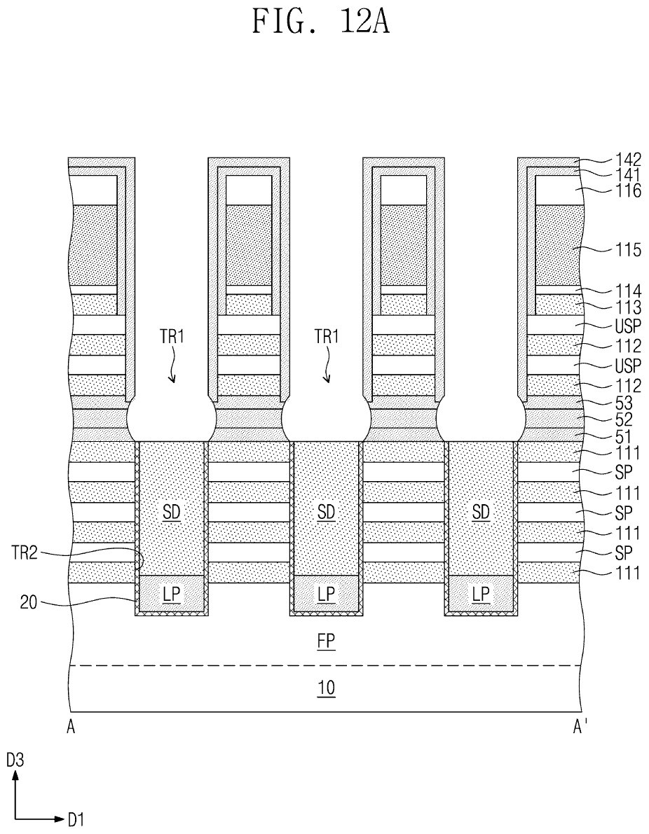

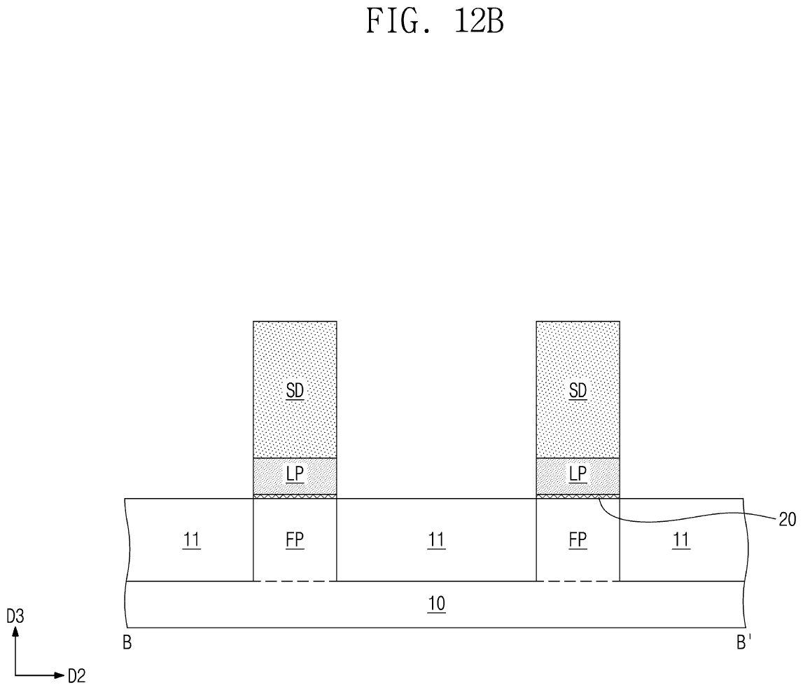

Referring to FIGS. 12A and 12B, the first preliminary two-dimensional layer p20 may be etched. In some implementations, the first preliminary two-dimensional layer p20 may be etched through a selective etching process. As a result of the etching of the first preliminary two-dimensional layer p20, the two-dimensional layers 20 may be formed. A portion of the first preliminary two-dimensional layer p20 left in the second trench TR2 may be defined as the two-dimensional layer 20.

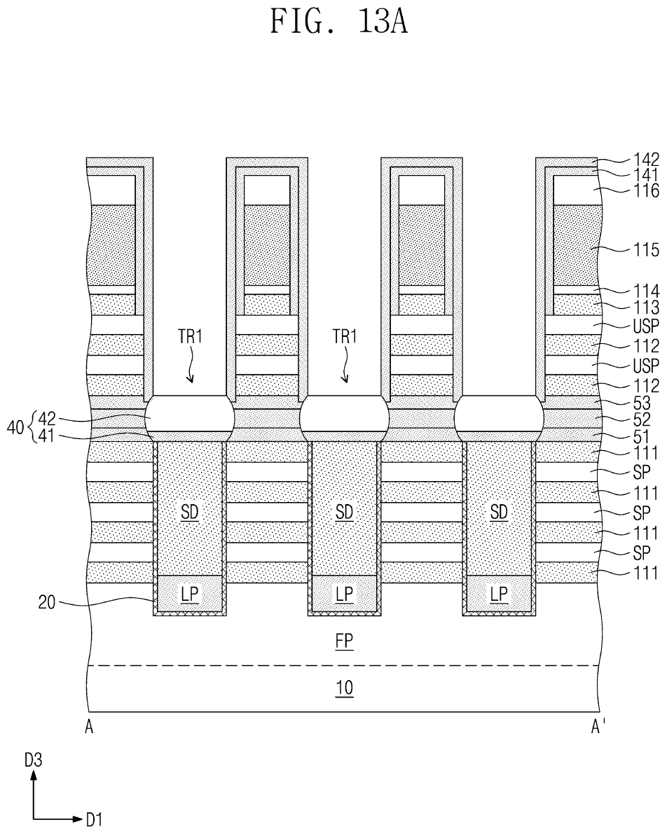

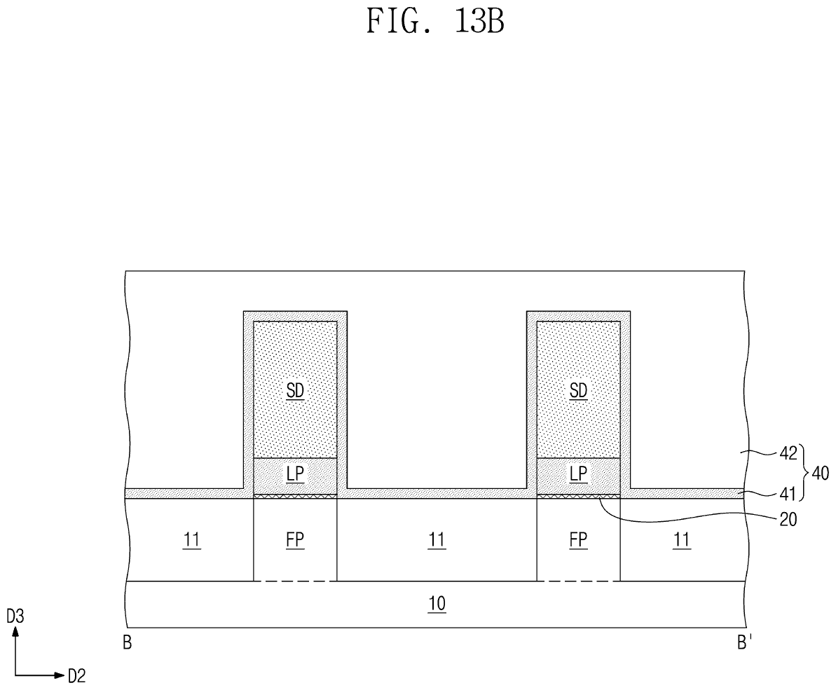

Referring to FIGS. 13A and 13B, the interlayered insulating structures 40 may be formed. The formation of the interlayered insulating structure 40 may include forming the interlayered liner 41 on the device isolation layer 11, the lower pattern LP, and the source/drain pattern SD and forming the interlayer insulating layer 42 on the interlayered liner 41.

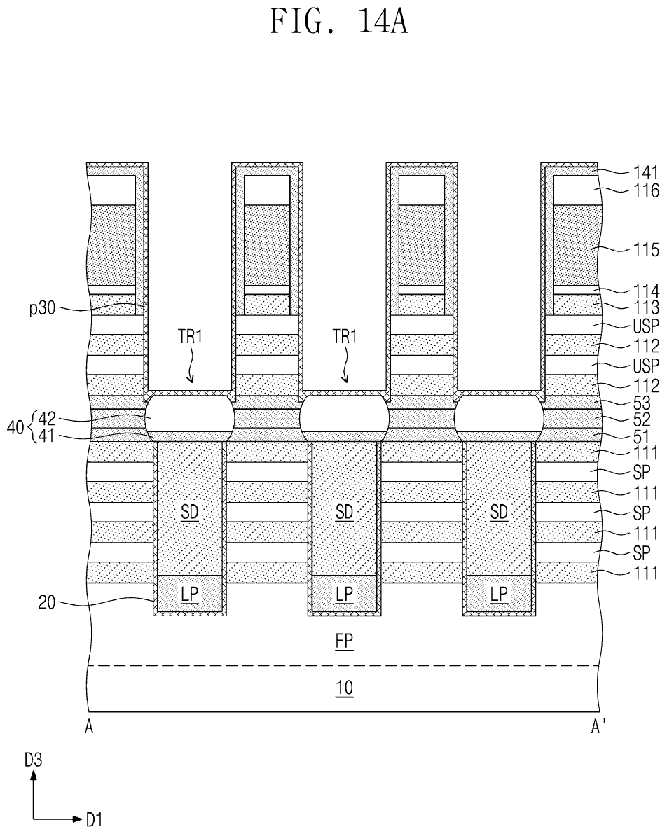

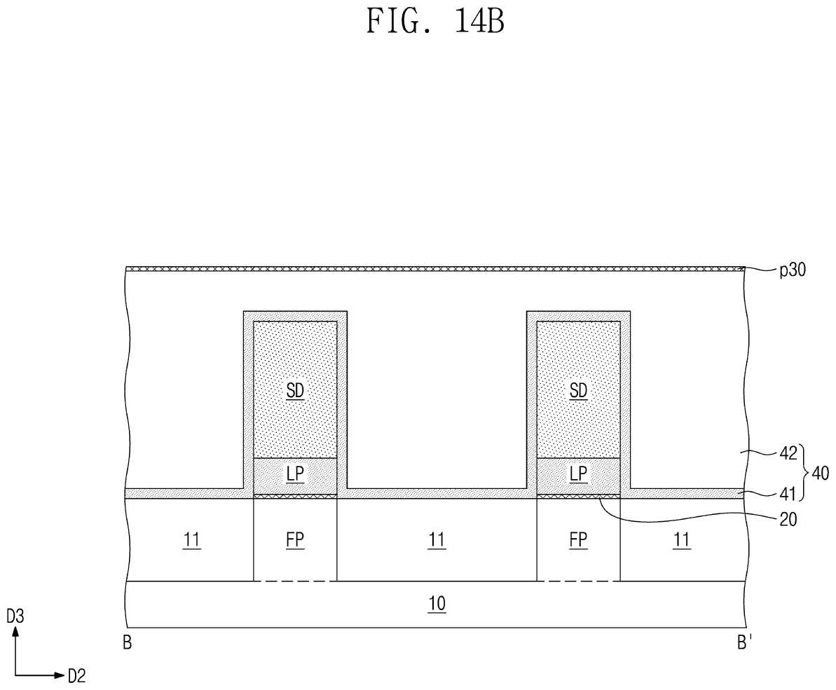

Referring to FIGS. 14A and 14B, the second preliminary insulating layer 142 may be removed. For example, the second preliminary insulating layer 142 may be removed to expose the second sacrificial layer 112, the upper semiconductor pattern USP, and the first preliminary insulating layer 141.

A second preliminary two-dimensional layer p30 may be formed. The second preliminary two-dimensional layer p30 may be formed by, for example, an ALD process. The second preliminary two-dimensional layer p30 may include a two-dimensional material.

The second preliminary two-dimensional layer p30 may include a portion formed in the first trench TR1. The second preliminary two-dimensional layer p30 may be formed on the second sacrificial layer 112, the upper semiconductor pattern USP, the interlayer insulating layer 42, and the first preliminary insulating layer 141.

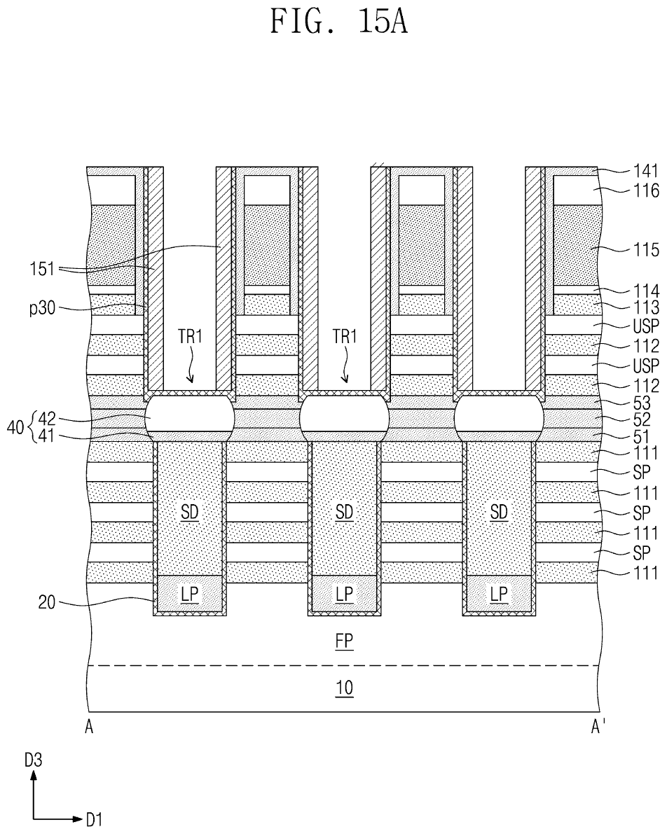

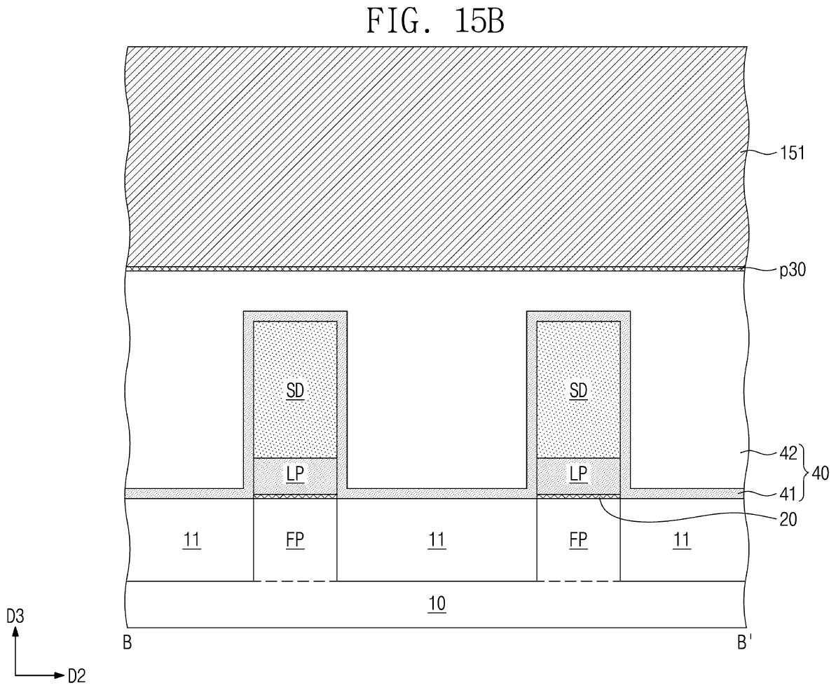

Referring to FIGS. 15A and 15B, sacrificial spacers 151 may be formed. The formation of the sacrificial spacers 151 may include forming a preliminary spacer layer on the second preliminary two-dimensional layer p30 and etching the preliminary spacer layer to form the sacrificial spacers 151. In some implementations, the second preliminary two-dimensional layer p30 may be etched in the step of etching the preliminary spacer layer and may be divided into a plurality of second preliminary two-dimensional layers p30.

The sacrificial spacer 151 may include a material having an etch selectivity with respect to the second preliminary two-dimensional layer p30. In some implementations, the sacrificial spacer 151 may include molybdenum (Mo).

The sacrificial spacer 151 may be disposed on the second preliminary two-dimensional layer p30. In the first trench TR1, two sacrificial spacers 151 may be spaced apart from each other in the first direction D1.

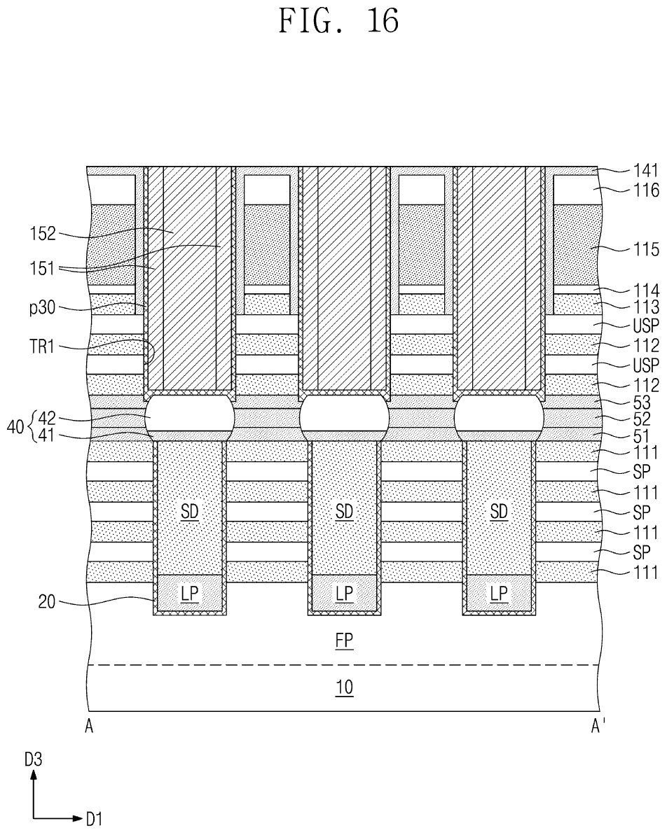

Referring to FIG. 16, filling patterns 152 may be formed. The filling pattern 152 may be provided between a pair of sacrificial spacers 151. The filling pattern 152 may fill the first trench TR1. The filling pattern 152 may be provided on the second preliminary two-dimensional layer p30.

The filling pattern 152 may include a material having an etch selectivity with respect to the sacrificial spacer 151 and the second preliminary two-dimensional layer p30. In some implementations, the filling pattern 152 may include LaO.

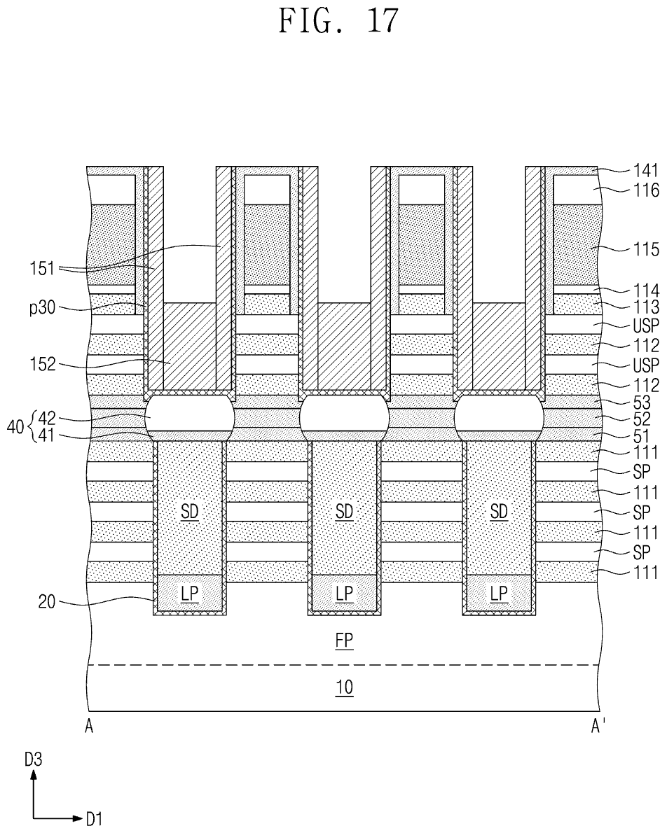

Referring to FIG. 17, the filling patterns 152 may be etched. The filling pattern 152 may be etched through a selective etching process.

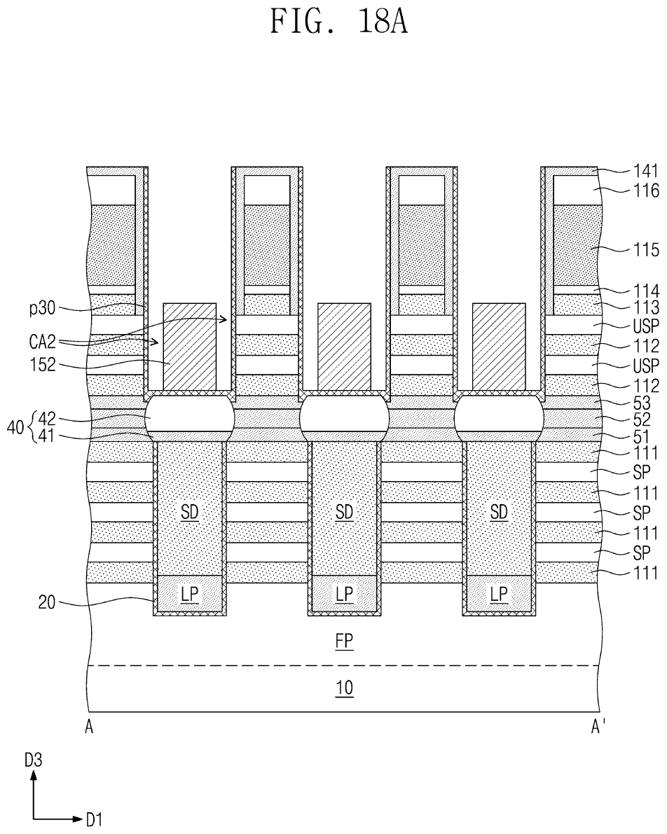

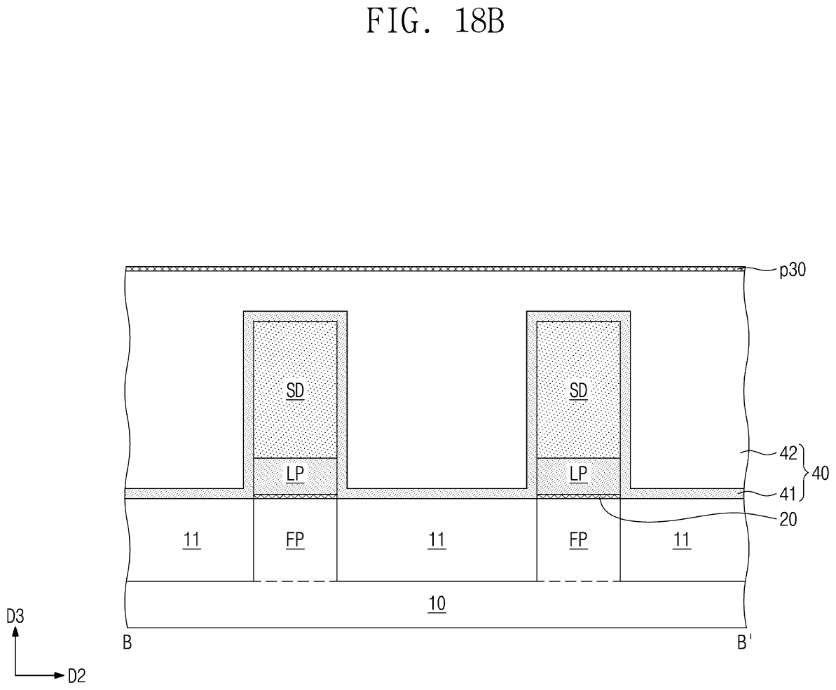

Referring to FIGS. 18A and 18B, the sacrificial spacers 151 may be removed. The sacrificial spacer 151 may be removed through a selective etching process. As a result of the removal of the sacrificial spacer 151, a second cavity CA2 may be formed between the filling pattern 152 and the second preliminary two-dimensional layer p30. The second cavity CA2 may be an empty space between the filling pattern 152 and the second preliminary two-dimensional layer p30.

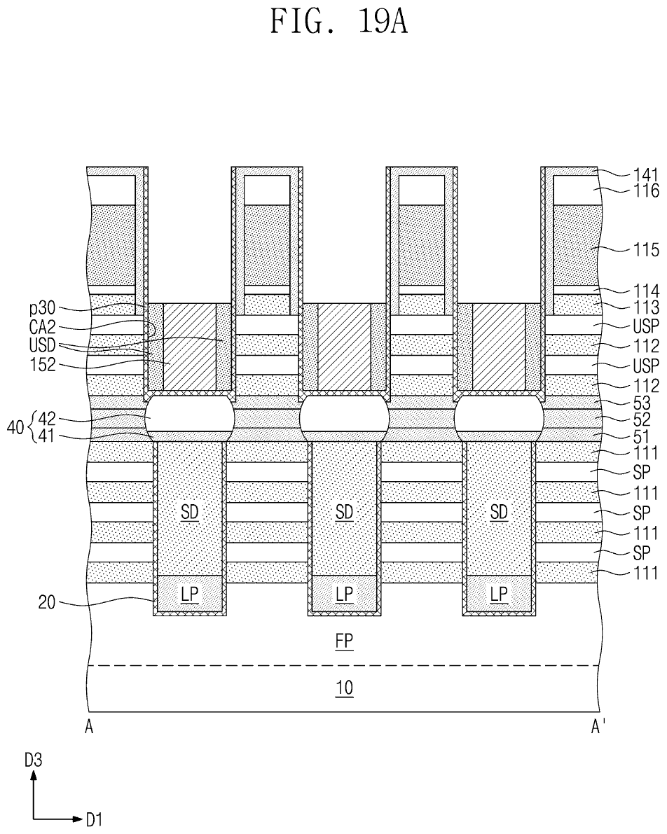

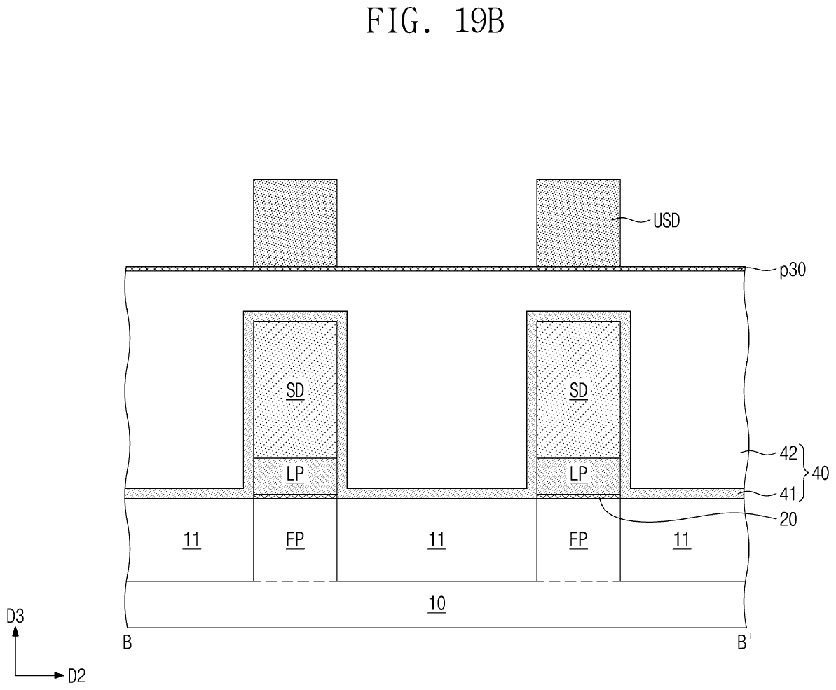

Referring to FIGS. 19A and 19B, the upper source/drain patterns USD may be formed. For example, the upper source/drain patterns USD may be formed by an epitaxial growth process using the upper semiconductor pattern USP and the second sacrificial layer 112 as a seed layer.

In some implementations, the second preliminary two-dimensional layer p30 may have a relatively small thickness, and in this case, the upper source/drain pattern USD may be formed through a remote epitaxial growth process, in which the upper semiconductor pattern USP and the second sacrificial layer 112 are used as a seed layer. In this case, a thickness of the second preliminary two-dimensional layer p30 may be less than or equal to 9 Å.

The upper source/drain pattern USD may fill the second cavity CA2.

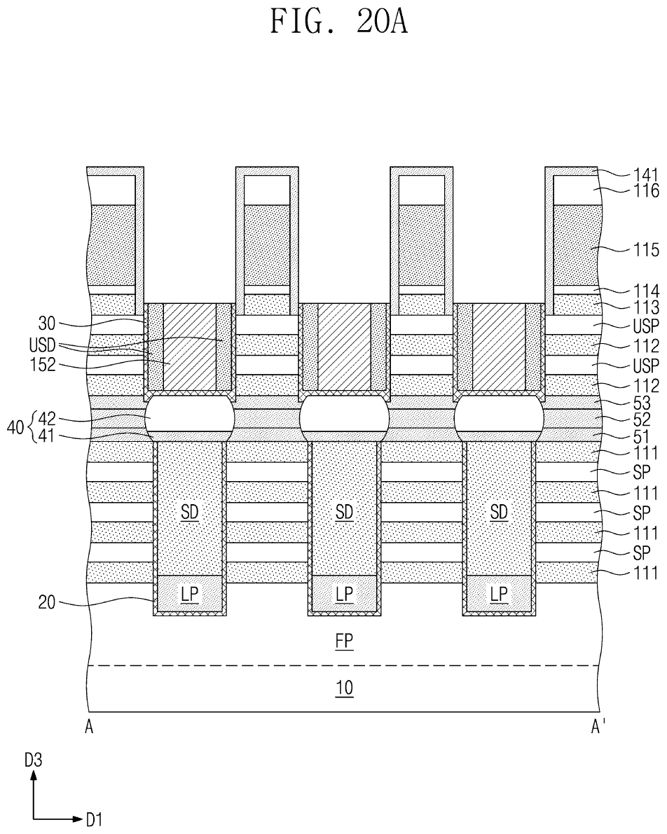

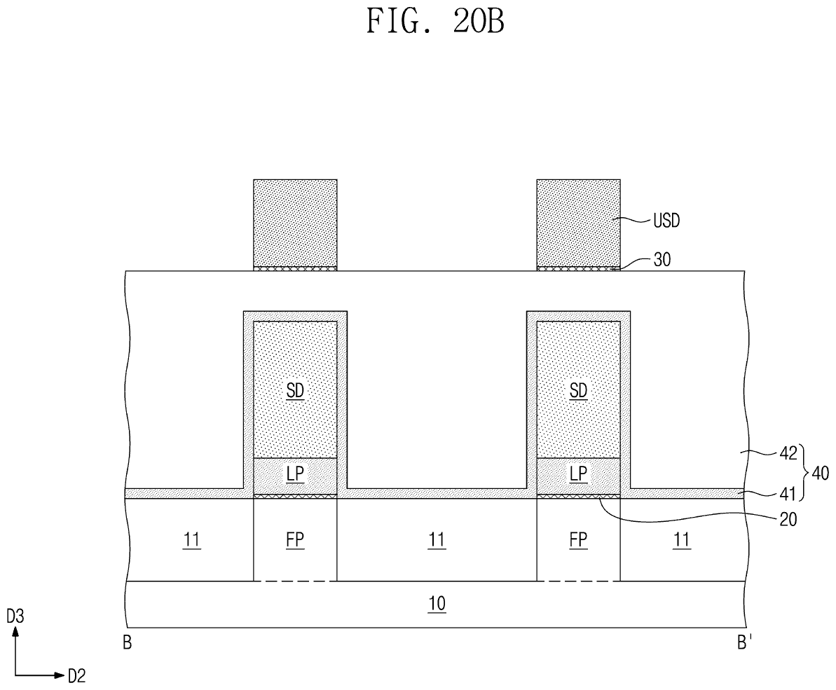

Referring to FIGS. 20A and 20B, the second preliminary two-dimensional layer p30 may be etched. In some implementations, the second preliminary two-dimensional layer p30 may be etched through a selective etching process. As a result of the etching of the second preliminary two-dimensional layer p30, the upper two-dimensional layers 30 may be formed.

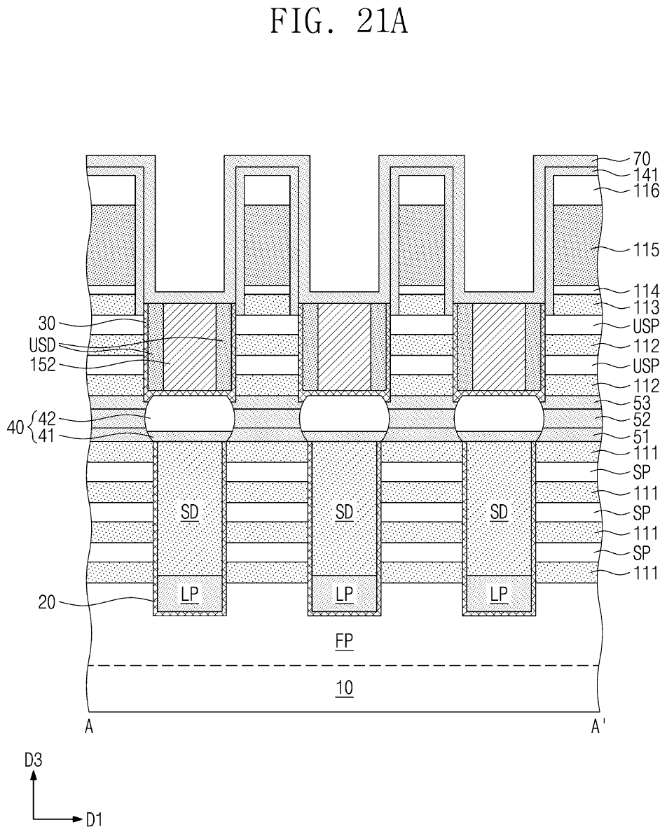

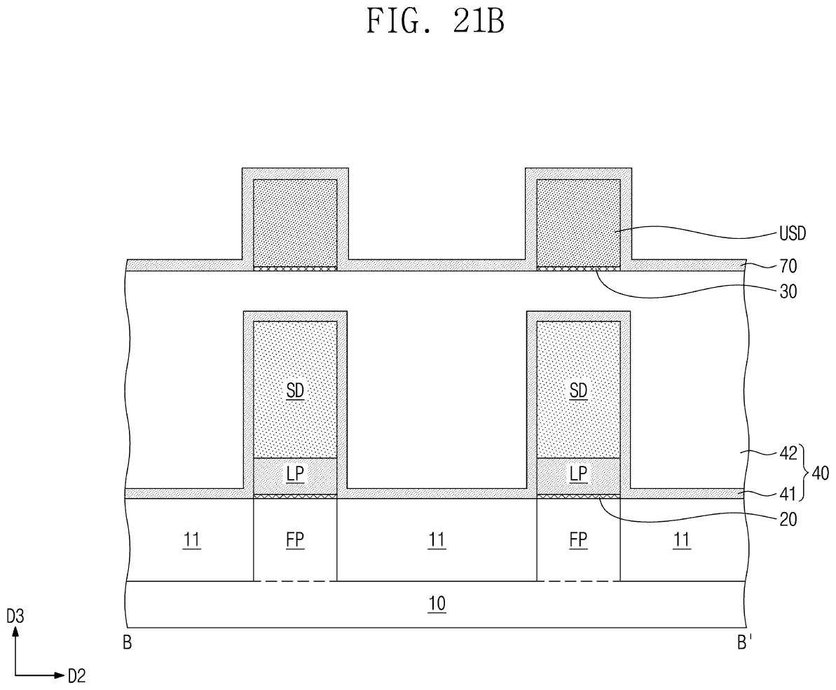

Referring to FIGS. 21A and 21B, the cover liner 70 may be formed. The cover liner 70 may cover the upper source/drain pattern USD, the first preliminary insulating layer 141, the filling pattern 152, and the interlayer insulating layer 42.

Referring to FIGS. 1A to 1E, a preliminary cover insulating layer may be formed on the cover liner 70. The cover liner 70 and the first preliminary insulating layer 141 may be etched. In some implementations, as a result of the etching of the first preliminary insulating layer 141, the first preliminary insulating layer 141 may be divided into the gate spacers GS.

In some implementations, the etching of the first preliminary insulating layer 141 may be performed to expose the mask pattern 116. The mask pattern 116, the sacrificial pattern 115, the sacrificial insulating layer 114, the third sacrificial layer 113, the second sacrificial layer 112, and the first sacrificial layer 111 may be removed. The third sacrificial layer 113, the second sacrificial layer 112, and the first sacrificial layer 111 may be removed by, for example, a fluorine-containing etching agent.

The inner spacer IG1, the upper inner spacer IG2, the gate insulating layer GI, the gate electrode GE, and the gate capping pattern GP may be formed. The inner spacer IG1, the upper inner spacer IG2, the gate insulating layer GI, the gate electrode GE, and the gate capping pattern GP may be formed in an empty space, which is formed by removing the sacrificial pattern 115, the sacrificial insulating layer 114, the third sacrificial layer 113, the second sacrificial layer 112, and the first sacrificial layer 111. In some implementations, the inner spacer IG1 and the upper inner spacer IG2 may be formed at the same time.

The inner spacer IG1 may be formed on a surface of the two-dimensional layer 20, which is exposed by removing the first sacrificial layer 111. The upper inner spacer IG2 may be formed on a surface of the upper two-dimensional layer 30, which is exposed by removing the second sacrificial layer 112. The gate division layers 65 may be formed.

The active contacts AC may be formed. In some implementations, the formation of the active contact AC may include etching the preliminary cover insulating layer, the cover liner 70, and the filling pattern 152, forming the cover insulating layer 60 in an empty space, which is formed by etching the preliminary cover insulating layer, the cover liner 70, and the filling pattern 152, etching the cover insulating layer 60 and the interlayered insulating structure 40, and forming the active contact AC in an empty space, which is formed by etching the cover insulating layer 60 and the interlayered insulating structure 40.

In a method of fabricating a semiconductor device according to some implementations, the two-dimensional layer 20 and the upper two-dimensional layer 30 may have a relatively high etch selectivity with respect to an etchant which is used for the process of removing the first and second sacrificial layers 111 and 112. Accordingly, even when the two-dimensional layer 20 and the upper two-dimensional layer 30 are relatively thin, the two-dimensional layer 20 and the upper two-dimensional layer 30 may protect the source/drain pattern SD and the upper source/drain pattern USD effectively.

In a method of fabricating a semiconductor device according to some implementations, since the inner spacer IG1 and the upper inner spacer IG2 are formed on the two-dimensional layer 20 and the upper two-dimensional layer 30 with flat side surfaces, the inner spacer IG1 and the upper inner spacer IG2 may also have flat side surfaces.

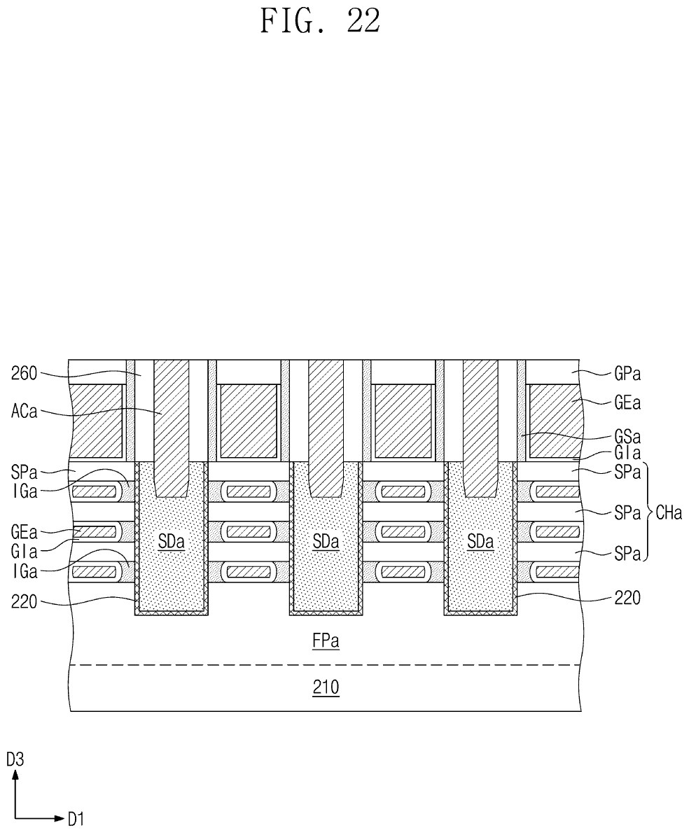

FIG. 22 is a sectional view illustrating an example of a semiconductor. The semiconductor device of FIG. 22 may be configured to have substantially the same features as the semiconductor device of FIGS. 1A to 1F, except for features to be described below.

Referring to FIG. 22, a substrate 210 including a fin pattern FPa, a channel structure CHa including semiconductor patterns SPa, a two-dimensional layer 220, a source/drain pattern SDa, an inner spacer IGa, a gate insulating layer GIa, a gate electrode GEa, a gate spacer GSa, and a gate capping pattern GPa may be provided.

A cover insulating layer 260 may be provided on the two-dimensional layer 220 and the source/drain pattern SDa. An active contact ACa may be provided to penetrate the cover insulating layer 260. The active contact ACa may be electrically connected to the source/drain pattern SDa.

In a semiconductor device according to some implementations, an inner spacer may have a relatively large width, and thus, a capacitance may be reduced.

In a semiconductor device according to some implementations, the inner spacer may have a flat side surface, and this may make it possible to reduce the capacitance.

In a semiconductor device according to some implementations, a germanium concentration in a source/drain pattern may be uniform throughout the entire region, and the performance of the semiconductor device may be improved.

In a semiconductor device according to some implementations, the germanium concentration in the source/drain pattern may be relatively high, and the electron mobility of the semiconductor pattern may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations of the present disclosure have been shown and described, it will be understood by one of ordinary skill in the art that variations in form and detail may be made therein without departing from the spirit and scope of the attached claims.

What is claimed is:

1. A semiconductor device comprising:
a first semiconductor pattern and a second semiconductor pattern;
a gate electrode including an electrode portion between the first semiconductor pattern and the second semiconductor pattern;
an inner spacer contacting a top surface of the first semiconductor pattern and a bottom surface of the second semiconductor pattern;
a two-dimensional layer contacting the first semiconductor pattern, the second semiconductor pattern, and the inner spacer; and
a source/drain pattern on the two-dimensional layer.

2. The semiconductor device of claim 1, wherein the two-dimensional layer contacts a side surface of the first semiconductor pattern, a side surface of the second semiconductor pattern, and a first side surface of the inner spacer, and
wherein the side surface of the first semiconductor pattern, the side surface of the second semiconductor pattern, and the first side surface of the inner spacer are flat.

3. The semiconductor device of claim 2, wherein the side surface of the first semiconductor pattern, the side surface of the second semiconductor pattern, and the first side surface of the inner spacer are coplanar with each other.

4. The semiconductor device of claim 2, wherein the inner spacer comprises a second side surface opposite to the first side surface of the inner spacer, and
wherein the second side surface of the inner spacer includes a curved shape.

5. The semiconductor device of claim 1, comprising:
a first upper semiconductor pattern and a second upper semiconductor pattern overlapping the first semiconductor pattern and the second semiconductor pattern;
an upper two-dimensional layer contacting the first upper semiconductor pattern and the second upper semiconductor pattern; and
an upper source/drain pattern on the upper two-dimensional layer,
wherein the upper two-dimensional layer overlaps the two-dimensional layer.

6. The semiconductor device of claim 5, comprising an active contact electrically connected with the upper source/drain pattern and the source/drain pattern,
wherein a side surface of the active contact contacts a side surface of the upper source/drain pattern.

7. The semiconductor device of claim 1, wherein the two-dimensional layer comprises a two-dimensional insulating material.

8. The semiconductor device of claim 1, wherein the source/drain pattern comprises a side surface contacting the two-dimensional layer, and
wherein the side surface of the source/drain pattern is flat.

9. A semiconductor device, comprising:
a first semiconductor pattern and a second semiconductor pattern;
a gate electrode including an electrode portion between the first semiconductor pattern and the second semiconductor pattern;
a two-dimensional layer contacting the first semiconductor pattern and the second semiconductor pattern;
an inner spacer between the two-dimensional layer and the electrode portion; and
a source/drain pattern on the two-dimensional layer,
wherein the inner spacer comprises a first side surface contacting the two-dimensional layer and a second side surface opposite to the first side surface, and
wherein an area of the first side surface of the inner spacer is smaller than an area of the second side surface of the inner spacer.

10. The semiconductor device of claim 9, wherein the first side surface of the inner spacer is flat, and
wherein the second side surface of the inner spacer includes a curved shape.

11. The semiconductor device of claim 9, wherein a thickness of the two-dimensional layer is less than or equal to 9 Å.

12. The semiconductor device of claim 9, comprising:
a first upper semiconductor pattern and a second upper semiconductor pattern overlapping the first semiconductor pattern and the second semiconductor pattern; and
an upper two-dimensional layer contacting the first upper semiconductor pattern and the second upper semiconductor pattern,
wherein the upper two-dimensional layer overlaps the two-dimensional layer.

13. The semiconductor device of claim 12, comprising:
a third semiconductor pattern spaced apart from the first semiconductor pattern in a first direction;
a fourth semiconductor pattern spaced apart from the second semiconductor pattern in the first direction;
a third upper semiconductor pattern spaced apart from the first upper semiconductor pattern in the first direction; and
a fourth upper semiconductor pattern spaced apart from the second upper semiconductor pattern in the first direction,
wherein the two-dimensional layer comprises a first portion and a second portion, the first portion of the two-dimensional layer contacting the first semiconductor pattern and the second semiconductor pattern, and the second portion of the two-dimensional layer contacting the third semiconductor pattern and the fourth semiconductor pattern, and
wherein the upper two-dimensional layer comprises a first portion and a second portion, the first portion of the upper two-dimensional layer contacting the first upper semiconductor pattern and the second upper semiconductor pattern, and the second portion of the upper two-dimensional layer contacting the third upper semiconductor pattern and the fourth upper semiconductor pattern.

14. The semiconductor device of claim 13, comprising:
an active contact between the first portion of the upper two-dimensional layer and the second portion of the upper two-dimensional layer,
a first upper source/drain pattern between the first portion of the upper two-dimensional layer and the active contact; and
a second upper source/drain pattern between the second portion of the upper two-dimensional layer and the active contact.

15. The semiconductor device of claim 14, wherein the active contact comprises a first side surface and a second side surface opposite to each other,
wherein the first side surface of the active contact contacts a side surface of the first upper source/drain pattern and a surface of the first portion of the upper two-dimensional layer,
wherein the second side surface of the active contact contacts a side surface of the second upper source/drain pattern and a surface of the second portion of the upper two-dimensional layer,
wherein the side surface of the first upper source/drain pattern and the surface of the first portion of the upper two-dimensional layer are coplanar with each other, and
wherein the side surface of the second upper source/drain pattern and the surface of the second portion of the upper two-dimensional layer are coplanar with each other.

16. The semiconductor device of claim 13, wherein a distance between the first portion of the two-dimensional layer and the second portion of the two-dimensional layer in the first direction is smaller than a distance between the first portion of the upper two-dimensional layer and the second portion of the upper two-dimensional layer in the first direction.

17. The semiconductor device of claim 9, wherein the two-dimensional layer comprises an outer side surface, the outer side surface of the two-dimensional layer contacting a side surface of the first semiconductor pattern, a side surface of the second semiconductor pattern, and the first side surface of the inner spacer,
wherein the outer side surface of the two-dimensional layer comprises a first portion contacting the side surface of the first semiconductor pattern, a second portion contacting the side surface of the second semiconductor pattern, and a third portion contacting the first side surface of the inner spacer, and
wherein the first portion, the second portion, and the third portion of the outer side surface of the two-dimensional layer are coplanar with each other.

18. A semiconductor device, comprising:
a first semiconductor pattern and a second semiconductor pattern;
a gate electrode including an electrode portion between the first semiconductor pattern and the second semiconductor pattern;
an inner spacer contacting a top surface of the first semiconductor pattern and a bottom surface of the second semiconductor pattern;
a gate insulating layer between the inner spacer and the electrode portion;
a two-dimensional layer contacting a side surface of the first semiconductor pattern, a side surface of the second semiconductor pattern, and a first side surface of the inner spacer;
a source/drain pattern on the two-dimensional layer; and
an active contact electrically connected with the source/drain pattern,
wherein the side surface of the first semiconductor pattern, the side surface of the second semiconductor pattern, and the first side surface of the inner spacer are coplanar with each other.

19. The semiconductor device of claim 18, comprising an upper two-dimensional layer overlapping the two-dimensional layer,
wherein the active contact is configured to extend through the upper two-dimensional layer.

20. The semiconductor device of claim 19, comprising a first upper source/drain pattern and a second upper source/drain pattern on the upper two-dimensional layer,
wherein the first upper source/drain pattern and the second upper source/drain pattern overlap the source/drain pattern.
